(19) United States
(12) Patent Application Publication
(10) Pub. No.: US 2024/0030128 A1
(43) Pub. Date: Jan. 25, 2024

(54) SEMICONDUCTOR DEVICES INCLUDING INDUCTOR STRUCTURES

(71) Applicant: Samsung Electronics Co., Ltd., Suwon-si (KR)

(72) Inventors: Jaepil Lee, Suwon-si (KR); Junbae Kim, Suwon-si (KR); Jinkwan Park, Suwon-si (KR)

(21) Appl. No.: 18/204,556

(22) Filed: Jun. 1, 2023

(30) Foreign Application Priority Data
Jul. 20, 2022 (KR) 10-2022-0089687

(51) Int. Cl. H01L 23/522; H10B 12/00

(52) U.S. Cl. CPC H01L 23/5227; H10B 12/00

(57) ABSTRACT

A semiconductor device may include a substrate, an element layer including circuit elements arranged on the substrate, a wiring layer on the element layer, and a redistribution layer on the wiring layer. The redistribution layer may include a redistribution insulating layer and a redistribution conductive layer on the redistribution insulating layer. The redistribution conductive layer may include a connection pad and first and second inductor structures respectively including first and second inductor redistribution lines having a planar coil shape, and a connection pad. The first and second inductor redistribution lines respectively included in the first and second inductor structures may have different thicknesses.

### CROSS-REFERENCE TO RELATED APPLICATION

This application is based on and claims priority under 35 U.S.C. § 119 to Korean Patent Application No. 10-2022-0089687, filed on Jul. 20, 2022, in the Korean Intellectual Property Office, and the entire contents of the above-identified application are incorporated by reference herein.

### TECHNICAL FIELD

The present disclosure relates to semiconductor devices, and more particularly, to semiconductor devices including inductor structures.

### BACKGROUND

As a result of rapid development in the electronics industry in order to meet accelerating demands of users, electronic devices are becoming smaller and faster, and exhibiting lower power consumption. Accordingly, it is increasingly desirable that semiconductor devices used in electronic devices exhibit high operating speeds and operate with various operating voltages. As such, the need for power management in electronic devices and/or semiconductor devices increases.

### SUMMARY

The present disclosure provides semiconductor devices including inductor structures that may respond to high operating speeds and/or various operating voltages.

The present disclosure provides at least the following semiconductor devices. According to some aspects of the inventive concepts, a semiconductor device may include a substrate, an element layer including circuit elements arranged on the substrate, a wiring layer on the element layer, and a redistribution layer on the wiring layer. The redistribution layer may include a redistribution insulating layer and a redistribution conductive layer on the redistribution insulating layer. The redistribution conductive layer may include a connection pad and first and second inductor structures respectively including first and second inductor redistribution lines having a planar coil shape. The first and second inductor redistribution lines respectively included in the first and second inductor structures may have different thicknesses.

According to other aspects of the inventive concepts, a semiconductor device may include a substrate, an element layer including circuit elements arranged on the substrate, a wiring layer formed on the element layer and including an inter-wiring insulating layer, a lower wiring line and an upper wiring line respectively on a lower surface and an upper surface of the inter-wiring insulating layer, and a wiring via passing through the inter-wiring insulating layer and electrically connecting the lower wiring line to the upper wiring line, a wiring contact plug electrically connecting the lower wiring line to the circuit element, and a redistribution layer formed on the wiring layer and including a redistribution insulating layer and a redistribution conductive layer, wherein the redistribution conductive layer includes a plurality of inductor redistribution lines each having a planar coil shape on the redistribution insulating layer, layer, a connection pad connected on the redistribution insulating layer, a connection pad connected redistribution line extending on the redistribution insulating layer, and a redistribution via that extends through the redistribution insulating layer and is electrically connected to the upper wiring line and to one the connection pad connected redistribution line or one of the inductor redistribution line, and the plurality of inductor redistribution lines include a first inductor redistribution line having a first thickness and a second inductor redistribution line having a second thickness that is less than the first thickness.

According to other aspects of the inventive concepts, a semiconductor device includes a substrate having an active region, a word line provided in the substrate, an element layer provided on the substrate and including a bit line connected to the active region through a direct contact, and a capacitor structure electrically connected to the active region through a buried contact and a landing pad, a wiring layer provided on the element layer, and including an inter-wiring insulating layer, a lower wiring line and an upper wiring line respectively on a lower surface and an upper surface of the inter-wiring insulating layer, and a wiring via passing through the inter-wiring insulating layer to electrically connect the lower wiring line to the upper wiring line, a redistribution layer including a redistribution insulating layer and a redistribution conductive layer on the wiring layer, and a protective layer covering part of the redistribution conductive layer on the redistribution insulating layer, wherein the redistribution conductive layer has a planar coil shape on the redistribution insulating layer and includes a plurality of inductor redistribution lines each constituting an inductor structure, a connection pad connected to a connection pad connected redistribution line on the redistribution insulating layer, and a redistribution via passing through the redistribution insulating layer and electrically connected to the upper wiring line and connected to the connection pad connected redistribution line or one of the inductor redistribution lines, the plurality of inductor redistribution lines include a first inductor redistribution line having a first thickness, a second inductor redistribution line having a second thickness that is less than the first thickness, and a third inductor redistribution line having a third thickness that is less than the second thickness, and the connection pad connected redistribution line and the connection pad have the first thickness.

### BRIEF DESCRIPTION OF THE DRAWINGS

Some examples of embodiments of the presently provided inventive concepts will be more clearly understood from the following detailed description taken in conjunction with the accompanying drawings in which:

FIG. 1 is a schematic cross-sectional view illustrating a semiconductor device according to some embodiments of the inventive concepts;

FIG. 2A is a view illustrating a semiconductor device according to some embodiments of the inventive concepts, and FIG. 2B is a schematic plan layout illustrating a semiconductor device according to some embodiments of the inventive concepts;

FIGS. 3A, 3B, 3C, 3D, 3E, and 3F are cross-sectional views of a semiconductor device, according to some example embodiments;

FIG. 4 is a conceptual plan layout illustrating a semiconductor device according to some example embodiments;

FIG. 5 is a cross-sectional view illustrating a semiconductor device according to some example embodiments;

FIGS. 6A, 6B, and 6C are cross-sectional views sequentially illustrating a method of manufacturing a semiconductor device, according to some example embodiments;

FIG. 7 is a cross-sectional view illustrating a method of manufacturing a semiconductor device, according to some example embodiments;

FIG. 8 is a cross-sectional view illustrating a semiconductor device according to some example embodiments;

FIGS. 9A, 9B, 9C, 9D, 9E, and 9F are cross-sectional views sequentially illustrating a method of manufacturing a semiconductor device, according to some example embodiments;

FIGS. 10A, 10B, and 10C are schematic plan views illustrating inductor structures included in a semiconductor device, according to some example embodiments; and

FIGS. 11A, 11B, and 11C are schematic plan views illustrating inductor structures included in a semiconductor device, according to some example embodiments.

### DETAILED DESCRIPTION

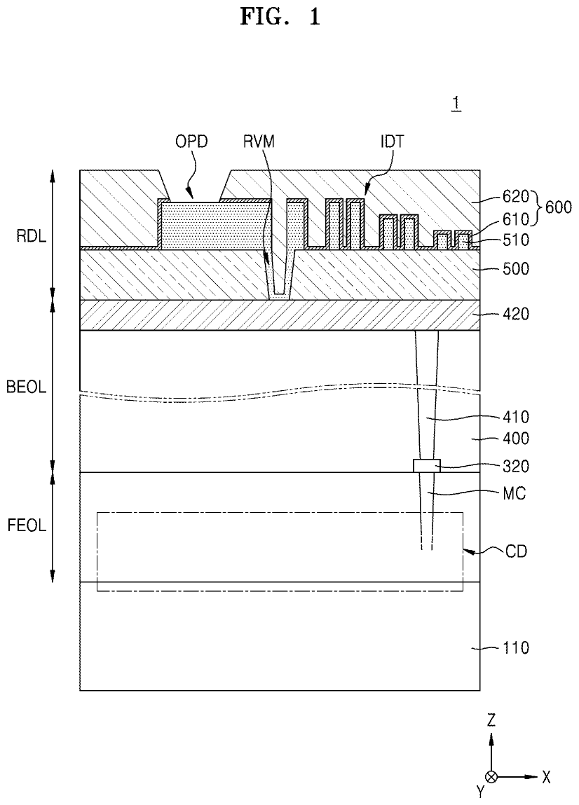

FIG. 1 is a schematic cross-sectional view illustrating a semiconductor device according to some embodiments of the inventive concepts.

Referring to FIG. 1, a semiconductor device 1 may include a substrate 110, an element layer FEOL, a wiring layer BEOL, and a redistribution layer RDL.

In some embodiments, the substrate 110 may include, for example, silicon (Si), crystalline Si, polycrystalline Si, or amorphous Si. In some other embodiments, the substrate 110 may include semiconductor elements such as germanium (Ge), or at least one compound semiconductor selected from a group of silicon germanium (SiGe), silicon carbide (SiC), gallium arsenide (GaAs), indium arsenide (InAs), and indium phosphide (InP). In some embodiments, the substrate 110 may have a silicon on insulator (SOI) structure. For example, the substrate 110 may include a buried oxide layer (BOX). The substrate 110 may include a conductive region, for example, a well doped with an impurity or a structure doped with an impurity.

The element layer FEOL may be formed on the substrate 110. A circuit element CD may be in the element layer FEOL. The circuit element CD may be formed in an upper portion of the substrate 110 and the element layer FEOL. The element layer FEOL may be referred to as a front end of line (FEOL) layer.

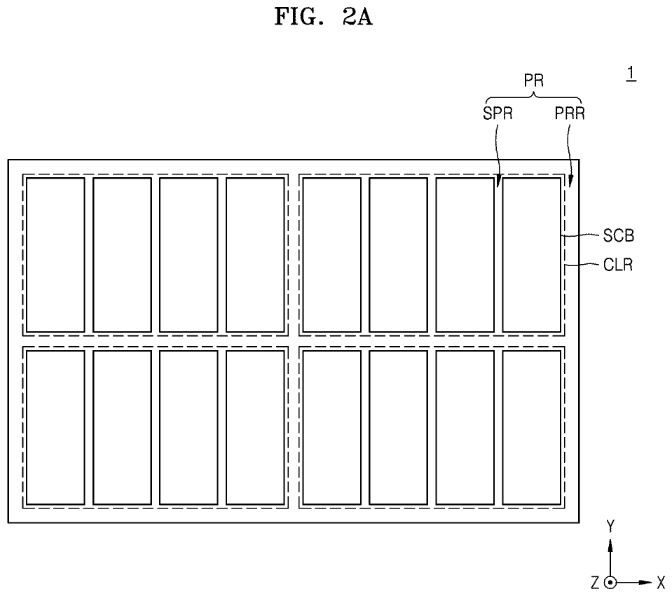

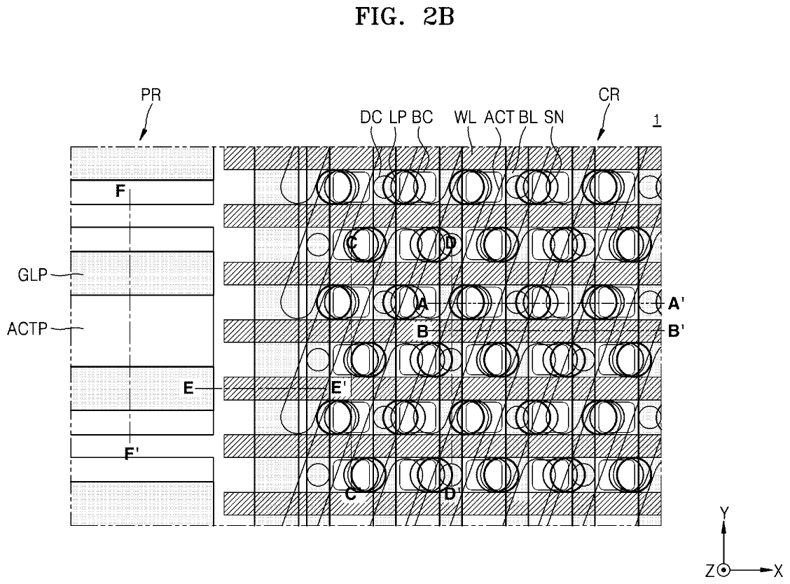

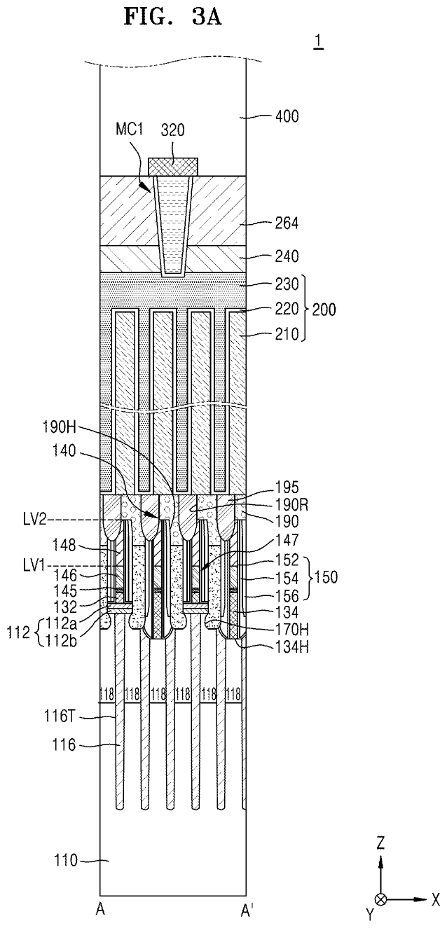

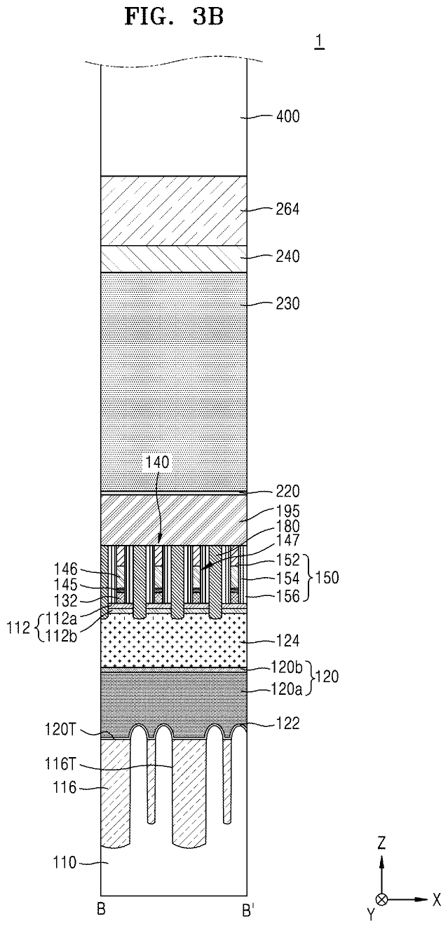

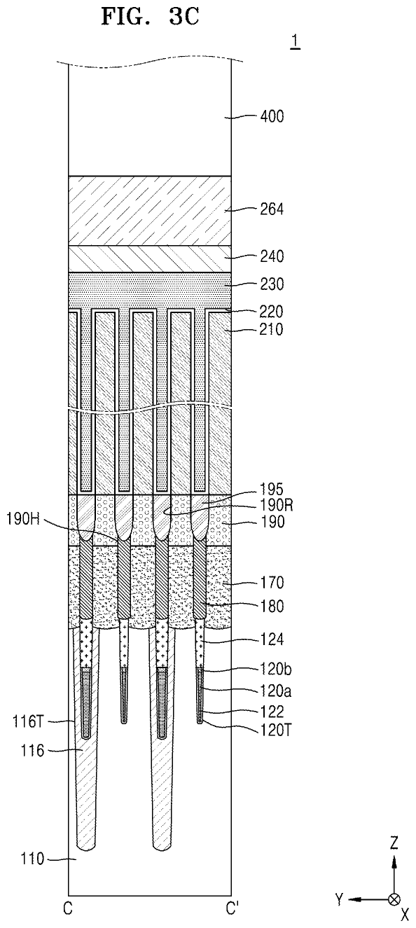

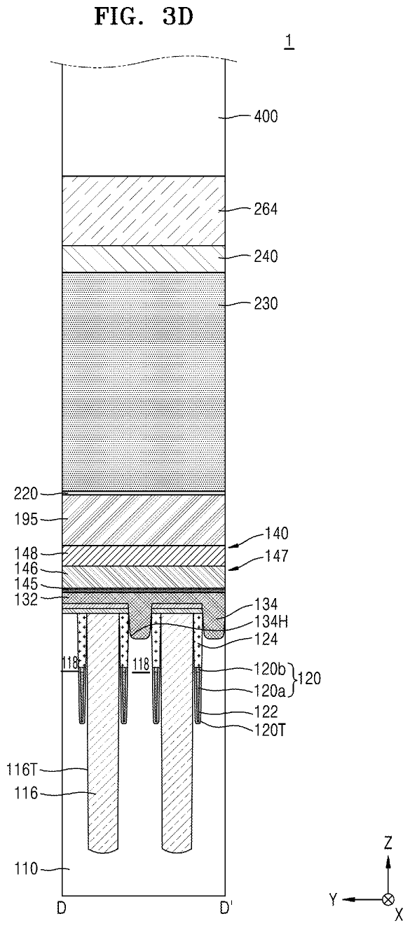

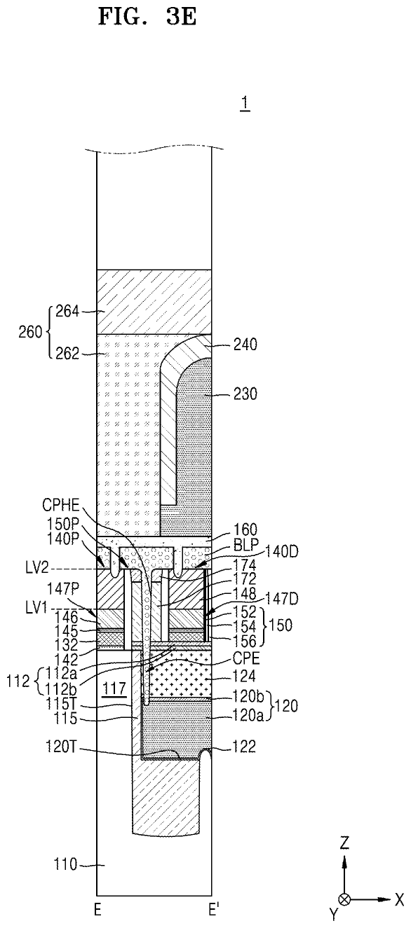

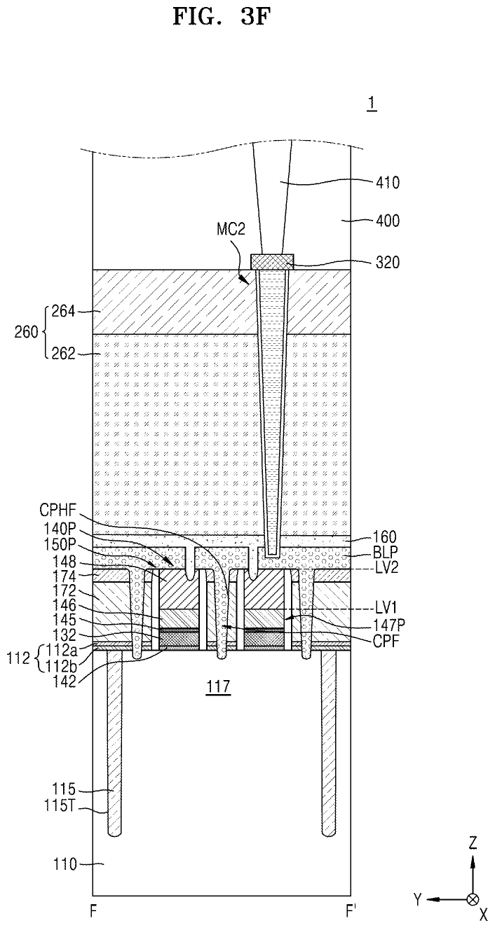

The circuit element CD may include a volatile memory element, such as dynamic random access memory (DRAM) or static random access memory (SRAM), a non-volatile memory element, such as flash memory, phase-change random access memory (PRAM), magnetoresistive random access memory (MRAM), ferroelectric random access memory (FeRAM), or resistive random access memory (RRAM), and/or a logic element, such as a central processing unit (CPU), a graphics processing unit (GPU), an application processor (AP), or a neural processing unit (NPU). FIGS. 2A to 3F illustrate an example in which the circuit element CD is DRAM, but the present disclosure is not limited thereto. The circuit element CD may include a variety of elements that may be included in a semiconductor circuit.

The wiring layer BEOL may be formed on the element layer FEOL. The wiring layer BEOL may include a lower wiring line 320, a wiring via 410, an upper wiring line 420, and an inter-wiring insulating layer 400. The wiring layer BEOL may also be referred to as a Back End of Line (BEOL) layer. The lower wiring line 320 may be at or near a lower surface of the inter-wiring insulating layer 400, the upper wiring line 420 may be on or near an upper surface of the inter-wiring insulating layer 400, and the wiring via 410 may extend within or pass through the inter-wiring insulating layer 400 to electrically connect the lower wiring line 320 to the upper wiring line 420.

FIG. 1 illustrates only the lower wiring line 320, the upper wiring line 420, and the wiring via 410 connecting the lower wiring line 320 to the upper wiring line 420 but this is an example and the present disclosure is not limited thereto. For example, the semiconductor device 1 may include three or more wiring lines at different vertical levels, and two or more wiring vias at different vertical levels to connect the wiring lines to each other. The lower wiring line 320 may be electrically connected to the element layer FEOL through a wiring contact plug MC that may be connected to a lower surface of the lower wiring line 320. For example, the lower wiring line 320 may be electrically connected to the circuit element CD through the wiring contact plug MC.

The lower wiring line 320, the wiring via 410, and the upper wiring line 420 may each be formed of a metal material, such as Al, W, Cu, Ti, Ta, Ru, Mn, or Co. For example, the lower wiring line 320, the wiring via 410, and the upper wiring line 420 may each include Al. The inter-wiring insulating layer 400 may be formed of silicon oxide or an insulating material having a lower dielectric permittivity than the dielectric permittivity of silicon oxide. In some embodiments, the inter-wiring insulating layer 400 may include a tetraethyl orthosilicate (TEOS) layer or an ultralow K (ULK) layer having an ultralow dielectric constant K of approximately 2.2 to 2.4. The ULK layer may include a SiOC layer or a SiCOH layer.

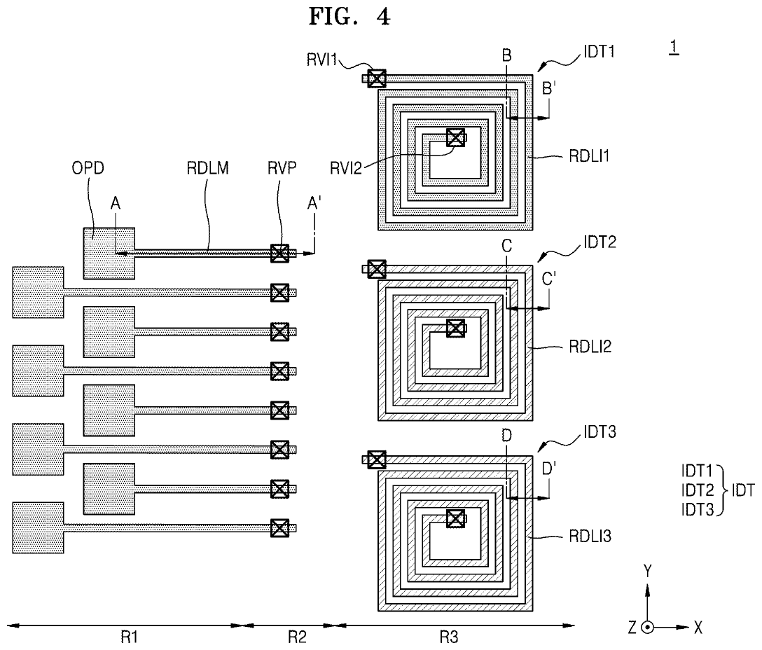

The redistribution layer RDL may be formed on the wiring layer BEOL. The redistribution layer RDL may include a redistribution insulating layer 500 and a redistribution conductive layer 510. The redistribution insulating layer 500 may be formed of silicon oxide, silicon nitride, or an insulating material having a lower dielectric permittivity than the dielectric permittivity of silicon oxide. For example, the redistribution insulating layer 500 may be formed of TEOS. The redistribution conductive layer 510 may be formed of a metal material, such as Al, W, Cu, Ti, Ta, Ru, Mn, or Co. For example, the redistribution conductive layer 510 may include Al. Each of a connection pad OPD, a redistribution via RVM, and an inductor structure IDT may include a respective portion of the redistribution conductive layer 510. The connection pad OPD and the inductor structure IDT may be on the redistribution insulating layer 500, and the redistribution via RVM may pass through the redistribution insulating layer 500 and be connected to the upper wiring line 420. The connection pad OPD, the redistribution via RVM, and the inductor structure IDT included in the redistribution layer RDL will be described in detail with reference to FIGS. 4 to 11C.

Although FIG. 1 illustrates an example of the redistribution via RVM as connecting the connection pad OPD to the upper wiring line 420, similar redistribution vias may also be connected to one or both ends of the redistribution conductive layer 510 including the inductor structure IDT and may connect the inductor structure IDT to the upper wiring line 420.

A protective layer 600 that covers at least a part of the redistribution conductive layer 510 may be formed on the redistribution insulating layer 500. In some embodiments, the protective layer 600 may include a lower protective layer 610 and an upper protective layer 620. As non-limiting examples, the lower protective layer 610 may include silicon nitride, and the upper protective layer 620 may be formed of photosensitive polyimide (PSPI), photo imageable dielectric (PID), epoxy, or polyimide. The lower protective layer 610 may cover a part of an upper surface of the redistribution conductive layer 510 and an upper surface of the redistribution insulating layer 500, and the upper protective layer 620 may cover the lower protective layer 610. The lower protective layer 610 may conform to and may cover a part of an upper surface of the redistribution conductive layer 510. Some portions of the redistribution conductive layer 510 may not be covered by the lower protective layer 610 and/or the upper protective layer 620. For example, the lower protective layer 610 may not cover an upper surface of the connection pad OPD in the redistribution conductive layer 510. The upper protective layer 620 may cover the lower protective layer 610 and have an upper surface higher than an upper surface of the redistribution conductive layer 510. The connection pad OPD may be a part of the redistribution conductive layer 510 not covered by the protective layer 600. The inductor structure IDT may not be exposed to the outside by being covered by the protective layer 600.

The semiconductor device 1 may include a plurality of inductor structures IDTs. At least two of the plurality of inductor structures IDT may be formed of redistribution conductive layers 510 having different thicknesses. At least one of the plurality of inductor structures IDT and the connection pad OPD may be formed of the redistribution conductive layer 510 having substantially the same thickness. A thickness of a component herein may refer to a height in a vertical or Z-direction.

At least two inductor structures IDT including redistribution conductive layers 510 having different thicknesses may have different inductances. For example, an inductance L of the inductor structure IDT of the redistribution conductive layer 510 may be L=2 l*(ln(l/ (t|w)|½) nH (nanohenry), where l, w, and t are respectively a length, a width, and a thickness of the redistribution conductive layer 510 of the inductor structure IDT having a unit of cm. Accordingly, when two inductor structures IDT having the same length and width have different thicknesses, the inductance of the inductor structure IDT having a relatively large thickness may be less than the inductance of the inductor structure IDT having a relatively small thickness.

The semiconductor device 1 according to the inventive concepts may have a plurality of inductor structures IDT formed by a redistribution conductive layer 510 in a redistribution layer RDL, and at least two of the plurality of inductor structures IDT may have different inductances. Accordingly, the plurality of inductor structures IDT included in the semiconductor device 1 may be used for various and different purposes. For example, at least one of the plurality of inductor structures IDT may be used as a radio frequency (RF) inductor that is electrically connected to the connection pad OPD for data signal input/output, and at least one of the other inductor structures IDT may be used as a power inductor that is electrically connected to a circuit for voltage modulation in a peripheral circuit region. For example, an inductor structure IDT having a relatively large thickness may be used as the RF inductor, and an inductor structure IDT having a relatively small thickness may be used as the power inductor. Alternatively, the inductor structures IDT having different thicknesses may include power inductors operating in response to different operating voltages from each other. Accordingly, the plurality of inductor structures IDT may include power inductors respectively corresponding to various operating voltages.

Accordingly, the semiconductor device 1 according to the inventive concepts may exhibit improved or increased operation reliability with inductors used for various purposes (e.g., RF inductors) even when an operation speed increases and/or may exhibit reduce power consumption, for example because the power inductors respectively corresponding to various operating voltages are included.

FIGS. 2A to 3F are diagrams or views illustrating circuit elements included in the semiconductor device according to some embodiments of the inventive concepts, and FIGS. 4 to 11C are views illustrating inductor structures included in semiconductor devices according to some embodiments of the inventive concepts.

FIG. 2A is a view illustrating a semiconductor device according to some embodiments of the inventive concepts, and FIG. 2B is a schematic plan layout illustrating a semiconductor device according to some embodiments of the inventive concepts.

Referring to FIG. 2A, the semiconductor device 1 may include cell regions CLR in which memory cells are arranged and a main peripheral region PRR surrounding the cell regions CLR.

According to some embodiments of the inventive concepts, the cell regions CLR may each include sub-peripheral regions SPR that divide or space apart cell blocks SCB. A plurality of memory cells may be arranged in each of the cell blocks SCB. The cell block SCB may be a region in which the memory cells are regularly arranged with uniform intervals, and the cell block SCB may be referred to as a sub-cell block.

Logic cells for inputting and outputting an electrical signal to and from the memory cells may be arranged in the main peripheral region PRR and the sub-peripheral region SPR. In some embodiments, the main peripheral region PRR may be referred to as a peripheral circuit region, and the sub-peripheral region SPR may be referred to as a core circuit region. A peripheral region PR may include the main peripheral region PRR and the sub-peripheral regions SPR. That is, the peripheral region PR may be a core/peripheral circuit region including the peripheral circuit region and the core circuit region. In some embodiments, at least some of the sub-peripheral regions SPR may be provided only as a space for dividing the cell blocks SCB.

In some embodiments, the connection pad OPD illustrated in FIG. 1 may be arranged on the cell block SCB, the redistribution via RVM may be arranged in the peripheral region PR, and the inductor structure IDT may be arranged in the peripheral region PR, but the present disclosure is not limited thereto.

Referring to FIG. 2B, the semiconductor device 1 includes a memory cell region CR and the peripheral region PR. The semiconductor device 1 may include a plurality of active regions ACT in the memory cell region CR, and a plurality of logic active regions ACTP in the peripheral region PR. The memory cell region CR may be the cell block SCB in which a plurality of memory cells illustrated in FIG. 2A are arranged, and the peripheral region PR may be the peripheral region PR including the main peripheral region PRR and the sub-peripheral regions SPR illustrated in FIG. 2A.

In some embodiments, the plurality of active regions ACT in the memory cell region CR may have long axes in a horizontal direction that is diagonal to or intersecting both a first horizontal direction (the X direction) and a second horizontal direction (the Y direction).

A plurality of word lines WL may extend in parallel to each other in the first horizontal direction (the X direction) across the plurality of active regions ACT in the memory cell region CR. A plurality of bit lines BL may extend in parallel to each other in the second horizontal direction (the Y direction) that crosses the first horizontal direction (the X direction). The plurality of bit lines BL may extend over the plurality of word lines WL. The plurality of bit lines BL may be connected to the plurality of active regions ACT through a plurality of direct contacts DC.

In some embodiments, a plurality of buried contacts BC may be between two adjacent bit lines BL among the plurality of bit lines BL. In some embodiments, the plurality of buried contacts BC may be arranged in a grid or lines in each of the first horizontal direction (the X direction) and the second horizontal direction (the Y direction).

A plurality of landing pads LP may be on the plurality of buried contacts BC. The plurality of landing pads LP may be arranged to at least partially overlap the plurality of buried contacts BC. In some embodiments, each of the plurality of landing pads LP may extend to an upper portion of one of the two adjacent bit lines BL.

A plurality of storage nodes SN may respectively be on the plurality of landing pads LP. The plurality of storage nodes SN may respectively be over the plurality of bit lines BL. Each of the plurality of storage nodes SN may be a lower electrode of each of a plurality of capacitors. The storage node SN may be connected to the active region ACT through the landing pad LP and the buried contact BC.

A plurality of gate line patterns GLP may be arranged over the logic active region ACTP in the peripheral region PR. FIG. 2B illustrates that the plurality of gate line patterns GLP extend in parallel to each other in the first horizontal direction (the X direction) over the logic active region ACTP and have substantially constant widths in the second horizontal direction (the Y direction) but the present disclosure is not limited thereto. For example, each of the plurality of gate line patterns GLP may have various widths or may vary in width and may have a curve or extend in various directions.

In FIG. 2B, components other than the plurality of logic active regions ACTP and the plurality of gate line patterns GLP are omitted in the peripheral region PR for the sake of convenience of illustration. In addition, although FIG. 2B illustrates that the plurality of gate line patterns GLP are arranged on only the plurality of logic active regions ACTP, the present disclosure is not limited thereto. For example, at least some of the plurality of gate line patterns GLP may extend outside the logic active region ACTP, that is, on a logic element isolation layer 115 of FIGS. 3E to 3F.

The plurality of gate line patterns GLP may be formed at the same level as the plurality of bit lines BL. In some embodiments, the plurality of gate line patterns GLP and the plurality of bit lines BL may be formed of the same material, or at least a part thereof may be formed of the same material. For example, a process of forming all or part of the plurality of gate line patterns GLP may be the same as a process of forming all or part of the plurality of bit lines BL.

FIGS. 3A to 3F are cross-sectional views of a semiconductor device, according to example embodiments. Specifically, FIG. 3A is a cross-sectional view taken along a position corresponding to line A-A′ of FIG. 2B, FIG. 3B is a cross-sectional view taken along a position corresponding to line B-B′ of FIG. 2B, FIG. 3C is a cross-sectional view taken along a position corresponding to line C-C′ of FIG. 2B, FIG. 3D is a cross-sectional view taken along a position corresponding to line D-D′ of FIG. 2B, FIG. 3E is a cross-sectional view taken along a position corresponding to line E-E′ of FIG. 2B, and FIG. 3F is a cross-sectional view taken along a position corresponding to line F-F′ of FIG. 2B. FIGS. 3A to 3F illustrate a part of the element layer FEOL and the wiring layer BEOL illustrated in FIG. 1.

Referring to FIGS. 3A to 3F, a semiconductor device 1 includes a substrate 110 having a plurality of active regions 118 and a plurality of logic active regions 117, a plurality of gate dielectric layers 122 sequentially formed in a plurality of word line trenches 120T crossing the plurality of active regions 118 in the substrate 110, a plurality of word lines 120, a plurality of buried insulating layers 124, an element isolation layer 116, an insulating layer pattern 112 covering the plurality of buried insulating layers 124, a plurality of bit line structures 140 on the insulating layer pattern 112, a plurality of insulating spacer structures 150 covering both sidewalls of the plurality of bit line structures 140, a plurality of gate line structures 140P on the plurality of logic active regions 117, a plurality of gate insulating spacers 150P covering both sidewalls of the plurality of gate line structures 140P, a plurality of landing pads 190 on upper portions of a plurality of buried contacts 170, which are within lower portions of spaces defined by the plurality of insulating fences 180 and the plurality of insulating spacer structures 150 and connected to the plurality of active regions 118, and extending to an upper portion of the bit line structure 140, and a plurality of capacitor structures 200 each including a plurality of lower electrodes 210 connected to the plurality of landing pads 190, a capacitor dielectric layer 220, and an upper electrode 230.

The element isolation layer 116 and the logic element isolation layer 115 may be formed by forming an element isolation trench 116T and a logic element isolation trench 115T in the substrate 110, and then filling the element isolation trench 116T and the logic element isolation trench 115T with an insulating material.

The element isolation layer 116 and the logic element isolation layer 115 may be formed of a material including at least one of, for example, a silicon oxide layer, a silicon nitride layer, and a silicon oxynitride layer. The element isolation layer 116 may include a single layer composed of one type of insulating layer, a double layer composed of two types of insulating layers, or a multilayer composed of a combination of at least three types of insulating layers. For example, the element isolation layer 116 may include a double layer or multiple layers including an oxide layer and a nitride layer. However, a configuration of the element isolation layer 116 is not limited to the above description. The plurality of active regions 118 may be defined in the substrate 110 by the element isolation layer 116 in the memory cell region CR of FIG. 2B, and the plurality of logic active regions 117 may be defined in the substrate 110 by the logic element isolation layer 115 in the peripheral region PR of FIG. 2B.

In some embodiments, the element isolation layer 116 and the logic element isolation layer 115 may be formed together, and may also be referred to as an element isolation structure. The element isolation layer 116 of the element isolation structure may define the plurality of active regions 118, and the logic element isolation layer 115 of the element isolation structure may define the plurality of logic active regions 117. The element isolation layer 116 may not be clearly distinguished from the logic element isolation layer 115 at a boundary between the memory cell region CR of FIG. 2B and the peripheral region PR of FIG. 2B.

The active regions 118 may have relatively long island shapes including a short axis and a long axis in a top or plan view, like the active regions ACT illustrated in FIG. 2B. Each of the logic active regions 117 may have a planar rectangular shape like the logic active regions ACTP illustrated in FIG. 2B but the present disclosure is not limited thereto and may have various planar shapes.

The plurality of word line trenches 120T may extend in the first horizontal direction (the X direction) in parallel to each other and may have line shapes or linear shapes. The plurality of word line trenches 120T may cross the active regions 118 at substantially equal intervals in the second horizontal direction (the Y direction). In some embodiments, there may be step differences between lower surfaces of the plurality of word line trenches 120T.

The plurality of gate dielectric layers 122, the plurality of word lines 120, and the plurality of buried insulating layers 124 may be sequentially formed in the plurality of word line trenches 120T. The plurality of word lines 120 may constitute the plurality of word lines WL illustrated in FIG. 2B. The plurality of word lines 120 may extend in the first horizontal direction (the X direction) in parallel to each other and may have line shapes or linear shapes. The plurality of word lines 120 may cross the active regions 118 at substantially equal intervals in the second horizontal direction (the Y direction). An upper surface of each of the plurality of word lines 120 may be at a level lower than an upper surface of the substrate 110. A lower surface of each of the plurality of word lines 120 may have an uneven shape, and saddle fin-shaped transistors (saddle FinFETs) may be formed in the plurality of active regions 118.

A level or a vertical level described in the present specification indicates a height in the vertical direction (the Z direction) with respect to a main surface or an upper surface of the substrate 110. That is, being at the same level or a constant level indicates a position in which the height in the vertical direction (the Z direction) with respect to the main surface or the upper surface of the substrate 110 is the same or constant, and being at a lower/higher level indicates a position in which a height in the vertical direction (the Z direction) with respect to the main surface of the substrate 110 is lower/higher.

Each of the plurality of word lines 120 may have a stacked structure of a lower word line layer 120a and an upper word line layer 120b. For example, the lower word line layer 120a may be formed of a metal material, a conductive metal nitride, or a combination thereof. In some embodiments, the lower word line layer 120a may be formed of Ti, TiN, Ta, TaN, W, WN, TiSiN, WSiN, or a combination thereof. For example, the upper word line layer 120b may be formed of doped polysilicon. In some embodiments, the lower word line layer 120a may include a core layer and a barrier layer between the core layer and the gate dielectric layer 122.

In some embodiments, there may be a source region and a drain region formed by injecting impurity ions in the active regions 118 of the substrate 110 on both sides of the plurality of word lines 120.

The gate dielectric layer 122 may include at least one selected from a silicon oxide layer, a silicon nitride layer, a silicon oxynitride layer, an oxide/nitride/oxide (ONO) layer, and a high-k dielectric layer having a higher dielectric constant than a dielectric constant of the silicon oxide layer. For example, the gate dielectric layer 122 may have a dielectric constant of about 10 to about 25.

The plurality of buried insulating layers 124 may be within the plurality of word line trenches 120T such that upper surfaces thereof are at substantially the same level as the upper surface of the substrate 110. The buried insulating layer 124 may include at least one selected from a silicon oxide layer, a silicon nitride layer, a silicon oxynitride layer, and a combination thereof.

The insulating layer pattern 112 may cover the element isolation layer 116, the plurality of active regions 118, the plurality of buried insulating layers 124, the logic element isolation layer 115, and the plurality of logic active regions 117. Each of a plurality of direct contact holes 134H may pass through the insulating layer pattern 112 to extend into the active region 118, that is, into the source region.

In some embodiments, the insulating layer pattern 112 may include a silicon oxide layer, a silicon nitride layer, a silicon oxynitride layer, a metal-based dielectric layer, and/or a combination thereof. In some embodiments, the insulating layer pattern 112 may be formed by stacking a plurality of insulating layers including the first insulating layer pattern 112a and the second insulating layer pattern 112b. In some embodiments, the first insulating layer pattern 112a may include a silicon oxide layer, and the second insulating layer pattern 112b may include a silicon oxynitride layer. In some other embodiments, the first insulating layer pattern 112a may include a non-metal-based dielectric layer, and the second insulating layer pattern 112b may include a metal-based dielectric layer.

The plurality of bit line structures 140 may extend in the second horizontal direction (the Y direction) parallel to the main surface of the substrate 110 in parallel to each other. Each of the plurality of bit line structures 140 may include a bit line 147 and an insulating capping line 148 covering the bit line 147. The bit line 147 and the insulating capping line 148 may have a line shape or linear shape. A plurality of bit lines 147 may constitute the plurality of bit lines BL illustrated in FIG. 2B. The bit line 147 may have a stacked structure of a first metal-based conductive pattern 145 and a second metal-based conductive pattern 146.

In some embodiments, the first metal-based conductive pattern 145 may be formed of titanium nitride (TiN) or TSN (Ti—Si—N), and the second metal-based conductive pattern 146 may be formed of tungsten (W), or tungsten and tungsten silicide (WSix). In some embodiments, the first metal-based conductive pattern 145 may function as a diffusion barrier. In some embodiments, the plurality of insulating capping lines 148 may each include a silicon nitride layer.

In some embodiments, the bit line structure 140 may further include a conductive semiconductor pattern 132 between the insulating layer pattern 112 and the first metal-based conductive pattern 145.

A plurality of direct contact conductive patterns 134 may be respectively in the plurality of direct contact holes 134H. The plurality of direct contact conductive patterns 134 may constitute the plurality of direct contacts DC illustrated in FIG. 2B. The plurality of bit lines 147 may be electrically connected to the plurality of active regions 118 through the plurality of direct contact conductive patterns 134.

The conductive semiconductor pattern 132 may be formed of, for example, doped polysilicon. The direct contact conductive pattern 134 may be formed of, for example, doped polysilicon. In some embodiments, the direct contact conductive pattern 134 may include an epitaxial silicon layer. During an etching process of forming the plurality of bit lines 147, the plurality of conductive semiconductor patterns 132 and the plurality of direct contact conductive patterns 134 may be formed. The plurality of conductive semiconductor patterns 132 and the plurality of direct contact conductive patterns 134 may vertically overlap or be overlapped by the plurality of bit lines 147.

Both sidewalls of each of the plurality of bit line structures 140 may be covered with an insulating spacer structure 150 of the plurality of insulating spacer structures 150. Each of the plurality of insulating spacer structures 150 may include a first insulating spacer 152, a second insulating spacer 154, and a third insulating spacer 156. The second insulating spacer 154 may be formed of a material having a lower dielectric permittivity than a dielectric permittivity of the first insulating spacer 152 and a dielectric permittivity of the third insulating spacer 156. In some embodiments, the first insulating spacer 152 and the third insulating spacer 156 may include a nitride layer, and the second insulating spacer 154 may include an oxide layer. In some embodiments, the first insulating spacer 152 and the third insulating spacer 156 may include a nitride layer, and the second insulating spacer 154 may be formed of a material having etch selectivity with respect to the first insulating spacer 152 and the third insulating spacer 156. For example, when the first insulating spacer 152 and the third insulating spacer 156 are composed of a nitride layer, the second insulating spacer 154 may be formed of an oxide layer but may be removed in a subsequent process to become an air spacer.

A plurality of buried contact holes 170H may be formed between the plurality of bit lines 147. An inner space of each of the plurality of buried contact holes 170H may be defined by insulating spacer structures 150 on sidewalls of each of two adjacent bit lines 147 and an active region 118, in a space between the two adjacent bit lines 147.

The plurality of buried contact holes 170H may be formed by removing a part of each of the insulating layer patterns 112 and a part of each of the active regions 118 by using the plurality of insulating capping lines 148 and the plurality of insulating spacer structures 150 covering sidewalls of the plurality of bit line structures 140 as etch masks. In some embodiments, the plurality of buried contact holes 170H may be formed to expand spaces defined by the active regions 118 by first performing an anisotropic etching process of removing a part of each of the insulating layer patterns 112 and a part of each of the active regions 118 by using the plurality of insulating capping lines 148 and the plurality of insulating spacer structures 150 covering sidewalls of the plurality of bit line structures 140 as etch masks, and then by performing an isotropic etching process to remove further parts of each of the active regions 118.

The plurality of gate line structures 140P may be formed on the plurality of logic active regions 117. In some embodiments, one or more dummy bit line structures 140D may be between the plurality of bit line structures 140 and the plurality of gate line structures 140P.

The plurality of gate line structures 140P may include a plurality of gate lines 147P and a plurality of insulating capping lines 148 covering the plurality of gate lines 147P. The plurality of gate lines 147P included in the plurality of gate line structures 140P may be formed together with the plurality of bit lines 147. That is, the plurality of gate lines 147P may each have a stacked structure of the first metal-based conductive pattern 145 and the second metal-based conductive pattern 146. A gate insulating layer pattern 142 may be between each of the plurality of gate lines 147P and the plurality of logic active regions 117. In some embodiments, each of the plurality of gate line structures 140P may further include a conductive semiconductor pattern 132 between the gate insulating layer pattern 142 and the first metal-based conductive pattern 145. The plurality of gate lines 147P may constitute the plurality of gate line patterns GLP illustrated in FIG. 2B.

Sidewalls of the plurality of gate line structures 140P may be covered by the plurality of gate insulating spacers 150P. The plurality of gate insulating spacers 150P may each include, for example, a nitride layer. In some embodiments, the plurality of gate insulating spacers 150P may each include a single layer but are not limited thereto, and may include a stacked structure of a plurality of layers, such as two or more layers.

The dummy bit line structures 140D may extend in parallel to each other in the second horizontal direction (the Y direction) together with the plurality of bit line structures 140. The dummy bit line structures 140D may each have a substantially similar structure to the bit line structure 140. The dummy bit line structures 140D may each include a dummy bit line 147D including the first metal-based conductive pattern 145 and the second metal-based conductive pattern 146, and the insulating capping line 148. At least one of the insulating spacer structure 150 and the gate insulating spacer 150P may cover a sidewall of the dummy bit line structure 140D.

In some embodiments, a width of the dummy bit line 147D in the first horizontal direction (the X direction) may be greater than a horizontal width of the bit line 147. In some other embodiments, the width of the dummy bit line 147D in the first horizontal direction (the X direction) may be equal to the horizontal width of the bit line 147. In some embodiments, there may be a plurality of dummy bit line structures 140D, and widths of the dummy bit lines 147D of some of the plurality of dummy bit line structures 140D in the first horizontal direction (the X direction) may be greater than the horizontal width of the bit line 147, and widths of the dummy bit lines 147D of other dummy bit line structures 140D in the first horizontal direction (the X direction) may have the same value as the horizontal width of the bit line 147.

The plurality of buried contacts 170 and the plurality of insulating fences 180 may be formed in spaces between the plurality of insulating spacer structures 150 covering both sidewalls of the plurality of bit line structures 140. The plurality of buried contacts 170 and the plurality of insulating fences 180 may be alternately arranged in the second horizontal direction (the Y direction) in a space between a pair of insulating spacer structures 150 that face each other in the first horizontal direction (the X direction) among the plurality of insulating spacer structures 150 covering both sidewalls of the plurality of bit line structures 140. The plurality of buried contacts 170 may be formed of polysilicon. For example, the plurality of insulating fences 180 may include a nitride layer.

In some embodiments, the plurality of buried contacts 170 may be arranged in a line in each of the first horizontal direction (the X direction) and the second horizontal direction (the Y direction). The plurality of buried contacts 170 may extend in the vertical direction (the Z direction) perpendicular to the substrate 110 from the plurality of active regions 118. The plurality of buried contacts 170 may constitute the plurality of buried contacts BC illustrated in FIG. 2B.

The plurality of buried contacts 170 may be arranged in spaces defined by the plurality of insulating fences 180 and the plurality of insulating spacer structures 150 on sidewalls of the plurality of bit line structures 140. The plurality of buried contacts 170 may each fill a part of each of lower portions of spaces between the plurality of insulating spacer structures 150 covering both sidewalls of the plurality of bit line structures 140.

Levels of upper surfaces of the plurality of buried contacts 170 may be lower than levels of upper surfaces of the plurality of insulating capping lines 148. The upper surfaces of the plurality of insulating fences 180 and the upper surfaces of the plurality of insulating capping lines 148 may be at the same level in the vertical direction (the Z direction).

A plurality of landing pad holes 190H may be defined by the plurality of insulating spacer structures 150 and the plurality of insulating fences 180. The plurality of buried contacts 170 may be exposed in lower surfaces of the plurality of landing pad holes 190H.

A stacked structure of a first filling insulating layer 172 and a second filling insulating layer 174 may be formed on the insulating layer pattern 112 around each of the plurality of gate line structures 140P. In some embodiments, the first filling insulating layer 172 may be formed of oxide, and the second filling insulating layer 174 may be formed of nitride. The upper surface of the second filling insulating layer 174 may have the same level as an upper surface of each of the plurality of gate line structures 140P.

The plurality of landing pads 190 may be separated from each other with recess portions 190R therebetween. The plurality of landing pads 190 may be on the plurality of buried contacts 170 and may extend on the plurality of bit line structures 140. In some embodiments, the plurality of landing pads 190 may extend on the plurality of bit lines 147. The plurality of landing pads 190 may be on the plurality of buried contacts 170, and the plurality of buried contacts 170 and the plurality of landing pads 190 corresponding to each other may be electrically connected to each other. The plurality of landing pads 190 may be connected to the plurality of active regions 118 through the plurality of buried contacts 170. The plurality of landing pads 190 may constitute the plurality of landing pads LP illustrated in FIG. 2B.

In some embodiments, the plurality of landing pads 190 may each include a conductive barrier layer and a conductive pad material layer on the conductive barrier layer. For example, the conductive barrier layer may be formed of a metal, a conductive metal nitride, or a combination thereof. In some embodiments, the conductive barrier layer may have a Ti/TiN stack structure. In some embodiments, the conductive pad material layer may include tungsten (W).

The plurality of buried contacts 170 may each be between two adjacent bit line structures 140, and the plurality of landing pads 190 may each extend on one bit line structure 140 from a space between two adjacent bit line structures 140 with the buried contact 170 therebetween. In some embodiments, an interface between the buried contact 170 and the landing pad 190 may be higher than a first vertical level LV1 of an upper surface of the second metal-based conductive pattern 146 and may be lower than a second vertical level LV2 of an upper surface of the insulating capping line 148.

In some embodiments, a metal silicide layer may be between the buried contact 170 and the landing pad 190. The metal silicide layer may be formed of cobalt silicide (CoSix), nickel silicide (NiSix), or manganese silicide (MnSix) but is not limited thereto.

A first contact hole CPHE and a second contact hole CPHF may pass through the second filling insulating layer 174, the first filling insulating layer 172, and the insulating layer pattern 112. The first contact hole CPHE and the second contact hole CPHF may be respectively referred to as a word line contact hole CPHE and a logic active region contact hole CPHF.

The word line contact hole CPHE may pass through the second filling insulating layer 174, the first filling insulating layer 172, the insulating layer pattern 112, the buried insulating layer 124, and the upper word line layer 120b to extend to the lower word line layer 120a. In some embodiments, the word line contact hole CPHE may extend into the lower word line layer 120a.

The logic active region contact hole CPHF may pass through the second filling insulating layer 174, the first filling insulating layer 172, and the insulating layer pattern 112 to extend to the logic active region 117. In some embodiments, the logic active region contact hole CPHF may extend into the logic active region 117.

In some embodiments, at least one of the first contact hole CPHE and the second contact hole CPHF may pass through the insulating capping line 148, and may extend to the second metal-based conductive pattern 146 or the first metal-based conductive pattern 145 that forms the gate line 147P or the bit line 147.

A first contact plug CPE may fill the first contact hole CPHE, and a second contact plug CPF may fill the second contact hole CPHF. The plurality of logic bit lines BLP may be on the plurality of insulating capping lines 148 and the second filling insulating layer 174. In some embodiments, the plurality of logic bit lines BLP may each be connected to the first contact plug CPE and the second contact plug CPF. In some embodiments, the plurality of logic bit lines BLP may each be formed (e.g., integrally formed) with the first contact plug CPE or the second contact plug CPF. In some embodiments, the first contact plug CPE, the second contact plug CPF, and the logic bit line BLP may be formed of the same material as the landing pad 190. For example, the logic bit line BLP may be higher than the second vertical level LV2, and the first contact plug CPE and the second contact plug CPF may be lower than the second vertical level LV2.

A capacitor structure 200 including the plurality of lower electrodes 210, the capacitor dielectric layer 220, and the upper electrode 230 may be on the plurality of landing pads 190. The plurality of lower electrodes 210 may be respectively and electrically connected to the plurality of landing pads 190. The capacitor dielectric layer 220 may conform to and cover surfaces of the plurality of lower electrodes 210. In some embodiments, the capacitor dielectric layer 220 may be formed (e.g., integrally formed) to cover the plurality of lower electrodes 210 together in a predetermined region, for example, in one memory cell region CR of FIG. 2B. In some other embodiments, the capacitor dielectric layer 220 may cover the memory cell region CR and the peripheral region PR of FIG. 2B together. The plurality of lower electrodes 210 may respectively constitute the plurality of storage nodes SN illustrated in FIG. 2B.

Each of the plurality of lower electrodes 210 may have a columnar shape with a filled inside to have a circular horizontal cross-section, that is, a pillar shape but is not limited thereto. In some embodiments, each of the plurality of lower electrodes 210 may have a cylindrical shape having a closed lower portion. In some embodiments, the plurality of lower electrodes 210 may have a honeycomb shape in which the plurality of lower electrodes 210 are arranged in a zigzag in the first horizontal direction (the X direction) or the second horizontal direction (the Y direction). In some other embodiments, the plurality of lower electrodes 210 may be arranged in a matrix form in which the plurality of lower electrodes 210 are arranged in a line in each of the first horizontal direction (the X direction) and the second horizontal direction (the Y direction). The plurality of lower electrodes 210 may be formed of, for example, a metal, such as silicon, tungsten, or copper which is doped with impurities, or a conductive metal compound, such as titanium nitride. Although not illustrated separately, the semiconductor device 1 may further include at least one support pattern in contact with sidewalls of the plurality of lower electrodes 210.

The capacitor dielectric layer 220 may be formed of, for example, TaO, TaAlO, TaON, AlO, AlSiO, HfO, HfSiO, ZrO, ZrSiO, TiO, TiAlO, BST((Ba,Sr)TiO), STO(SrTiO), BTO(BaTiO)·), PZT(Pb(Zr,Ti)O), (Pb,La)(Zr,Ti)O, Ba(Zr,Ti)O, Sr(Zr,Ti)O, or a combination thereof.

Before the plurality of lower electrodes 210 are formed, an insulating structure 195 filling the recess portion 190R may be formed. In some embodiments, the insulating structure 195 may include an interlayer insulating layer and an etch stop layer. For example, the interlayer insulating layer may include an oxide layer, and the etch stop layer may include a nitride layer. FIGS. 3A and 3C illustrate that an upper surface of the insulating structure 195 and a lower surface of the lower electrode 210 are at the same level as each other but are not limited thereto.

Before the plurality of lower electrodes 210 and the capacitor dielectric layer 220 are filled, a logic capping layer 160 covering the plurality of logic bit lines BLP may be formed. The logic capping layer 160 may be formed of, for example, silicon nitride. In some embodiments, the logic capping layer 160 may cover upper surfaces of the plurality of logic bit lines BLP. In some other embodiments, the logic capping layer 160 may fill spaces between the plurality of logic bit lines BLP and may not cover the upper surfaces of the plurality of logic bit lines BLP.

The upper electrode 230 may cover an upper portion of the capacitor dielectric layer 220 and may be in spaces between the plurality of lower electrodes 210. The upper electrode 230 may include doped polysilicon, doped polycrystalline silicon germanium (SiGe), or a metal-based material with conductivity. For example, the upper electrode 230 may be formed of Ru, RuO, Pt, PtO, Ir, IrO, SRO(SrRuO), BSRO((Ba,Sr)RuO), CRO(CaRuO), BaRuO, or La(Sr,Co). In some embodiments, the upper electrode 230 may be formed of a metal. For example, the upper electrode 230 may be formed of W.

The etch stop layer 240 may cover the upper electrode 230. The etch stop layer 240 may cover an upper surface of the upper electrode 230 and may not cover the logic capping layer 160. For example, the etch stop layer 240 may overlap the upper electrode 230 in the vertical direction (the Z direction) and may not overlap the logic capping layer 160. The etch stop layer 240 may be formed of Si, Ge, or at least one combination of O, N, C, B, H, and F. The etch stop layer 240 may be formed of, for example, SiO, SiN, SiCN, SiON, or SiBN. In some embodiments, the etch stop layer 240 may be formed of silicon oxynitride or silicon nitride. For example, the etch stop layer 240 may have a thickness of about 300 Å to about 1500 Å.

The buried insulating layer 262 may be in a portion at a level lower than the uppermost portion of the etch stop layer 240. The buried insulating layer 262 may be formed by forming a buried insulating material layer and then partially removing an upper portion of the buried insulating material layer by performing a chemical mechanical polishing (CMP) process using the etch stop layer 240 as a process stopper. A cover insulating layer 264 may cover the buried insulating layer 262 and the etch stop layer 240. The buried insulating layer 262 and the cover insulating layer 264 may constitute a filling insulating layer 260. The cover insulating layer 264 may be formed of, for example, silicon oxide. In some embodiments, the buried insulating layer 262 and the cover insulating layer 264 may be formed of the same material. The buried insulating layer 262 and the cover insulating layer 264 may include, for example, an oxide layer or an ultralow K (ULK) layer. The oxide layer is formed of any one selected from borophosphosilicate glass (BPSG), phosphosilicate glass (PSG), borosilicate glass (BSG), un-doped silicate glass (USG), tetra ethyl ortho silicate (TEOS), and high density plasma (HDP) layer. The ULK layer may include any one selected from, for example, an SiOC layer and a SiCOH layer with an ultralow dielectric constant K of 2.2 to 2.4.

The semiconductor device 1 may further include a first wiring contact plug MC1 and a second wiring contact plug MC2. The second wiring contact plug MC2 may have a vertical height greater than a vertical height of the first wiring contact plug MC1. For example, an upper surface of the first wiring contact plug MC1 may be at the same vertical level as an upper surface of the second wiring contact plug MC2, and a lower surface of the first wiring contact plug MC1 may be at a vertical level higher than a lower surface of the second wiring contact plug MC2.

The lower wiring line 320 may be formed on the filling insulating layer 260 to be connected to the first wiring contact plug MC1 and the second wiring contact plug MC2. The first wiring contact plug MC1 may electrically connect the lower wiring line 320 to the upper electrode 230. The second wiring contact plug MC2 may electrically connect the lower wiring line 320 to the logic bit line BLP. In some embodiments, the second wiring contact plug MC2 and the logic bit line BLP connected to the second wiring contact plug MC2 may electrically connect the lower wiring line 320 to the gate line 147P, the lower wiring line 320 to the word line 120, or the lower wiring line 320 to the logic active region 117.

The first wiring contact plug MC1 may pass through the filling insulating layer 260, that is, the cover insulating layer 264, and the etch stop layer 240 and may extend to the upper electrode 230. For example, the first wiring contact plug MC1 may extend into the upper electrode 230. In some embodiments, the first wiring contact plug MC1 may have a lower surface at a vertical level lower than an upper surface of the upper electrode 230. In some embodiments, the first wiring contact plug MC1 may extend into the upper electrode 230 and may not be in contact with the capacitor dielectric layer 220.

The second wiring contact plug MC2 may pass through the filling insulating layer 260, that is, the cover insulating layer 264 and the buried insulating layer 262, and the logic capping layer 160 and may extend to the logic bit line BLP. For example, the second wiring contact plug MC2 may extend into the logic bit line BLP. In some embodiments, the logic bit line BLP may have a stacked structure of a bit line barrier layer and a bit line conductive layer. In some embodiments, the second wiring contact plug MC2 may extend into the bit line conductive layer of the logic bit line BLP and may not be in contact with the bit line barrier layer.

The etch stop layer 240 that covers an upper surface of the upper electrode layer 230 electrically connected to the first wiring contact plug MC1 and surrounding the first wiring contact plug MC1 may be formed of a material that is different from a material forming the logic capping layer 160 that covers an upper surface of the logic bit line BLP electrically connected to the second wiring contact plug MC2 and surrounding the second wiring contact plug MC2. In some embodiments, the etch stop layer 240 may be formed of silicon oxynitride, and the logic capping layer 160 may be formed of silicon nitride. In some other embodiments, the etch stop layer 240 and the logic capping layer 160 may be formed of silicon nitride having different stoichiometric ratios.

In some embodiments, the first wiring contact plug MC1 and the second wiring contact plug MC2 may be the wiring contact plugs MC illustrated in FIG. 1. For example, the connection pad OPD illustrated in FIG. 1 may be electrically connected to the upper electrode 230 through the redistribution via RVM, the upper wiring line 420, and the first wiring contact plug MC1 or may be electrically connected to the logic active region 117 through the redistribution via RVM, the upper wiring line 420, and the second wiring contact plug MC2. For example, the inductor structure IDT illustrated in FIG. 1 may be electrically connected to the logic active region 117 through the redistribution via RVM, the upper wiring line 420, and the second wiring contact plug MC2.

FIG. 4 is a conceptual plan layout illustrating some configurations of a semiconductor device according to some embodiments of the inventive concepts.

Referring to FIG. 4, the semiconductor device 1 may include a first region R1, a second region R2, and a third region R3. A plurality of connection pads OPD may be in the first region R1. A plurality of inductor structures IDT may be in the third region R3. A first redistribution via RVI1 and a second redistribution via RVI2 may be connected to both ends of each of the plurality of inductor structures IDT. A plurality of third redistribution vias RVP may be in the second region R2. The plurality of connection pads OPD and the plurality of third redistribution vias RVP may be connected through a plurality of redistribution lines RDLM. The plurality of redistribution lines RDLM may be connection pad connected redistribution lines RDLM. The plurality of redistribution lines RDLM may be arranged to be partially included in the first region R1 and the second region R2. Although FIG. 4 illustrates that each of the plurality of connection pads OPD has a rectangular planar shape, the present disclosure is not limited thereto. For example, the plurality of connection pads OPD may have a polygonal shape, a circular shape, or an elliptical planar shape.

The first region R1 may include the cell blocks SCB illustrated in FIG. 2A, and the second region R2 and the third region R3 may include the peripheral regions PR illustrated in FIG. 2A, but the present disclosure is not limited thereto. In some embodiments, the second region R2 may include the sub-peripheral region SPR illustrated in FIG. 2A, and the third region R3 may include the main peripheral region PRR illustrated in FIG. 2A.

Each of the first redistribution via RVI1, the second redistribution via RVI2, and the third redistribution via RVP may be formed similarly to the redistribution via RVM illustrated in FIG. 1 to be connected to the upper wiring line 420.

In some embodiments, the plurality of inductor structures IDT may include a first inductor structure IDT1, a second inductor structure IDT2, and a third inductor structure IDT3. The first inductor structure IDT1 may include a first inductor redistribution line RDLI1 extending in a planar coil shape. The second inductor structure IDT2 may include a second inductor redistribution line RDLI2 extending in a planar coil shape. The third inductor structure IDT3 may include a third inductor redistribution line RDLI3 extending in a planar coil shape. The first redistribution via RVI1 and the second redistribution via RVI2 may be respectively connected to both ends of each of the first inductor redistribution line RDLI1, the second inductor redistribution line RDLI2, and the third inductor redistribution line RDLI3.

The plurality of connection pads OPD, the redistribution line RDLM, the first redistribution via RVI1, the second redistribution via RVI2, the third redistribution via RVP, the first inductor redistribution line RDLI1, the second inductor redistribution line RDLI2, and the third inductor redistribution line RDLI3 may be formed of the same material.

A thickness of the first inductor redistribution line RDLI1 may be substantially the same as a thickness of each of the plurality of connection pads OPD and a thickness of the redistribution line RDLM. A thickness of the second inductor redistribution line RDLI2 may be less than the thickness of the first inductor redistribution line RDLI1. A thickness of the third inductor redistribution line RDLI3 may be less than the thickness of the second inductor redistribution line RDLI2. Among the first inductor redistribution line RDLI1, the second inductor redistribution line RDLI2, and the third inductor redistribution line RDLI3 included in the plurality of inductor structures IDT, the first inductor redistribution line RDLI1 may have the greatest or largest thickness.

When extension lengths and widths of the first inductor redistribution line RDLI1, the second inductor redistribution line RDLI2, and the third inductor redistribution line RDLI3 are the same as each other, the third inductor structure IDT3 may have a greater inductance than the second inductor structure IDT2, and the second inductor structure IDT2 may have greater inductance than the first inductor structure IDT1. Accordingly, the plurality of inductor structures IDT included in the semiconductor device 1 may be used for various purposes, for example, as RF inductors or power inductors. For example, the first inductor structure IDT1 may include an RF inductor, and at least one of the second inductor structure IDT2 and the third inductor structure IDT3 may include a power inductor.

In some embodiments, widths of the first inductor redistribution line RDLI1, the second inductor redistribution line RDLI2, and the third inductor redistribution line RDLI3 may be the same as each other. For example, the width of each of the first inductor redistribution line RDLI1, the second inductor redistribution line RDLI2, and the third inductor redistribution line RDLI3 may be several μm. A width of each of the plurality of redistribution lines RDLM may be greater than or equal to a width of each of the first inductor redistribution line RDLI1, the second inductor redistribution line RDLI2, and the third inductor redistribution line RDLI3. The width of each of the plurality of connection pads OPD may be greater than widths of the first inductor redistribution line RDLI1, the second inductor redistribution line RDLI2, the third inductor redistribution line RDLI3, and the plurality of redistribution lines RDLM.

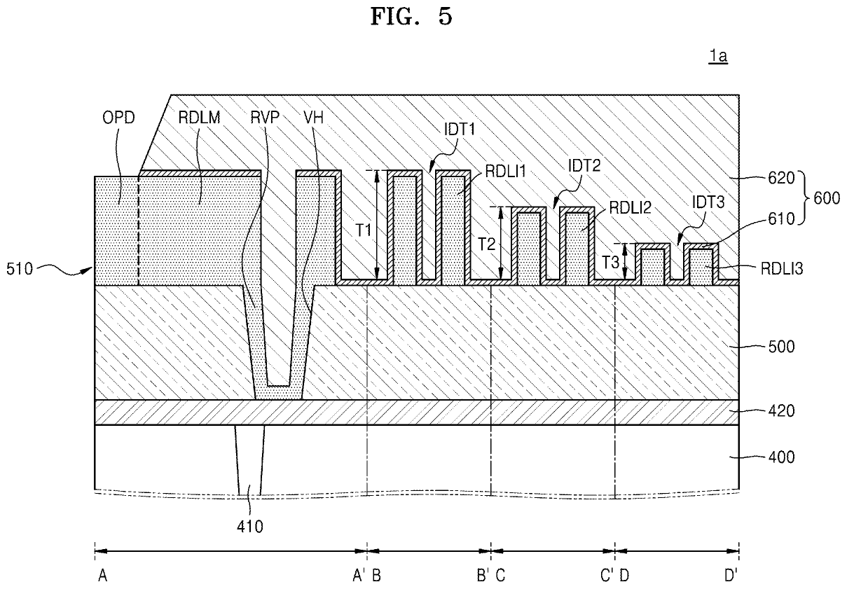

FIGS. 5 to 9F are cross-sectional views taken along line A-A′, line B-B′, line C-C′, and line D-D′ of FIG. 4.

FIG. 5 is a cross-sectional view illustrating a semiconductor device according to some example embodiments. FIG. 5 illustrates a part of the wiring layer BEOL illustrated in FIG. 1 and a portion corresponding to the redistribution layer RDL.

Referring to FIG. 5, a semiconductor device la may include an inter-wiring insulating layer 400, an upper wiring line 420 on the inter-wiring insulating layer 400, and a wiring via 410 in contact with a lower surface of the upper wiring line 420 and passing through the inter-wiring insulating layer 400.

A redistribution insulating layer 500 may be on the inter-wiring insulating layer 400 and the upper wiring line 420. For example, the redistribution insulating layer 500 may have a thickness of several μm. The redistribution insulating layer 500 may have a redistribution via hole VH. The redistribution via hole VH may pass through the redistribution insulating layer 500 to expose a part of the upper wiring line 420 at a lower surface of the redistribution via hole VH.

The redistribution conductive layer 510 may be on the redistribution insulating layer 500 and in the redistribution via hole VH. For example, the redistribution conductive layer 510 may have a thickness of several μm based on an upper surface of the redistribution insulating layer 500. The redistribution conductive layer 510 may cover a part of the upper surface of the redistribution insulating layer 500 and may fill at least a part of the redistribution via hole VH. The portion of the redistribution conductive layer 510 which fills the redistribution via hole VH may be a third redistribution via RVP. Although FIG. 5 illustrates only the third redistribution via RVP, the first redistribution via RVI1 and the second redistribution via RVI2 illustrated in FIG. 4 may also be formed similarly to the third redistribution via RVP. For example, the first redistribution via RVI1 and the second redistribution via RVI2 illustrated in FIG. 4 may include the portion of the redistribution conductive layer 510 which fills at least a part of another redistribution via hole VH, and may be connected to a first inductor redistribution line RDLI1, a second inductor redistribution line RDLI2, or a third inductor redistribution line RDLI3 instead of a redistribution line RDLM.

The portion of the redistribution conductive layer 510 which covers the upper surface of the redistribution insulating layer 500 may be a connection pad OPD, the redistribution line RDLM, the first inductor redistribution line RDLI1, the second inductor redistribution line RDLI2, or the third inductor redistribution line RDLI3. The redistribution line RDLM may connect the connection pad OPD to a third redistribution via RVP. In some embodiments, the connection pad OPD, the redistribution line RDLM, and the third redistribution via RVP may be integrally formed. Each of the first inductor redistribution line RDLI1, the second inductor redistribution line RDLI2, and the third inductor redistribution line RDLI3 may extend in a planar coil shape on the redistribution insulating layer 500. The first inductor redistribution line RDLI1, the second inductor redistribution line RDLI2, and the third inductor redistribution line RDLI3 may respectively configure a first inductor structure IDT1, a second inductor structure IDT2, and a third inductor structure IDT3.

Lower surfaces of the connection pad OPD, the redistribution line RDLM, the first inductor redistribution line RDLI1, the second inductor redistribution line RDLI2, and the third inductor redistribution line RDLI3 may be in contact with the upper surface of the redistribution insulating layer 500. In some embodiments, lower surfaces of the connection pad OPD, the redistribution line RDLM, the first inductor redistribution line RDLI1, the second inductor redistribution line RDLI2, and the third inductor redistribution line RDLI3 may be at the same vertical level. Upper surfaces of the connection pad OPD, the redistribution line RDLM, and the first inductor redistribution line RDLI1 may be at the same vertical level.

The connection pad OPD and the redistribution line RDLM may have a first thickness T1. The first inductor redistribution line RDLI1 may have substantially the same thickness as the connection pad OPD and the redistribution line RDLM, that is, the first thickness T1. The second inductor redistribution line RDLI2 may have a second thickness T2 less than the first thickness T1. The third inductor redistribution line RDLI3 may have a third thickness T3 less than the second thickness T2. For example, the first thickness T1 may be about 3 μm to about 9 μm, the second thickness T2 may be about 2 μm to about 6 μm, and the third thickness T3 may be about 1 μm to about 4 μm.

Although FIG. 5 illustrated that the semiconductor device la includes the first inductor structure IDT1, the second inductor structure IDT2, and the third inductor structure IDT3 respectively having the first thickness T1, the second thickness T2, and the third thickness T3, the present disclosure is not limited thereto. For example, the semiconductor device la may include two inductor structures or four or more inductor structures respectively having two different thicknesses or four or more different thicknesses.

For example, when extension lengths and widths of the first inductor redistribution line RDLI1, the second inductor redistribution line RDLI2, and the third inductor redistribution line RDLI3 are the same as each other, the third inductor structure IDT3 may have greater inductance than the second inductor structure IDT2, and the second inductor structure IDT2 may have greater inductance than the first inductor structure IDT1. Inductance of each of the first inductor structure IDT1, the second inductor structure IDT2, and the third inductor structure IDT3 may be about 0.1 nH to about 0.5 nH.

A protective layer 600 covering at least a part of the redistribution conductive layer 510 may be formed on the redistribution insulating layer 500. In some embodiments, the protective layer 600 may include a lower protective layer 610 and an upper protective layer 620. The lower protective layer 610 may cover a part of an upper surface of the redistribution conductive layer 510 and an upper surface of the redistribution insulating layer 500, and the upper protective layer 620 may cover the lower protective layer 610. The lower protective layer 610 may conform to and cover a part of the upper surface of the redistribution conductive layer 510. For example, the lower protective layer 610 may not cover an upper surface of the connection pad OPD in the redistribution conductive layers 510. The upper protective layer 620 may cover the lower protective layer 610 and have an upper surface higher than the upper surface of the redistribution conductive layer 510. On the upper surface of the redistribution insulating layer 500, the upper protective layer 620 may have a thickness greater than the first thickness T1. For example, the lower protective layer 610 may have a thickness of several thousand Å, and the upper protective layer 620 may have a thickness of about 5 μm to about 12 μm on the upper surface of the redistribution insulating layer 500.

The connection pad OPD may include a part of the redistribution conductive layer 510 that is not covered by the protective layer 600. The first inductor structure IDT1, the second inductor structure IDT2, the third inductor structure IDT3, the redistribution line RDLM, and the third redistribution via RVP may be covered by the protective layer 600 so as not to be exposed to the outside.

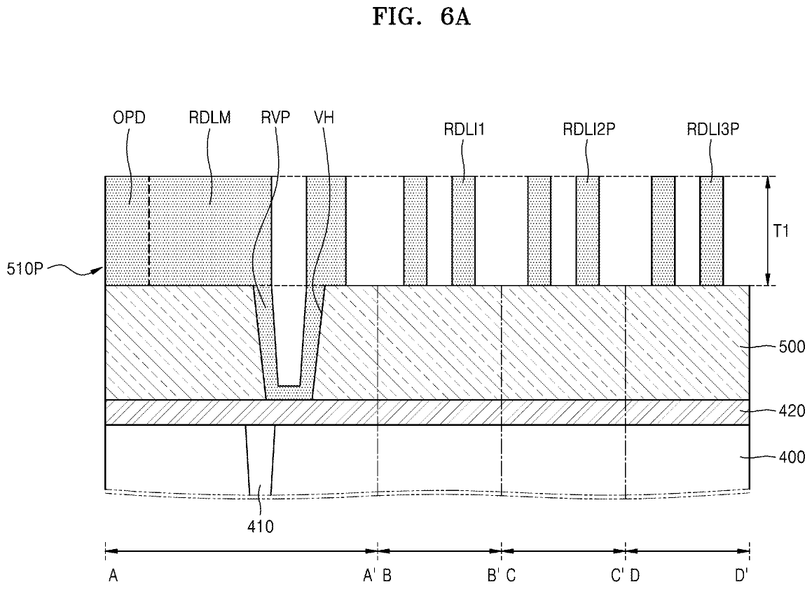

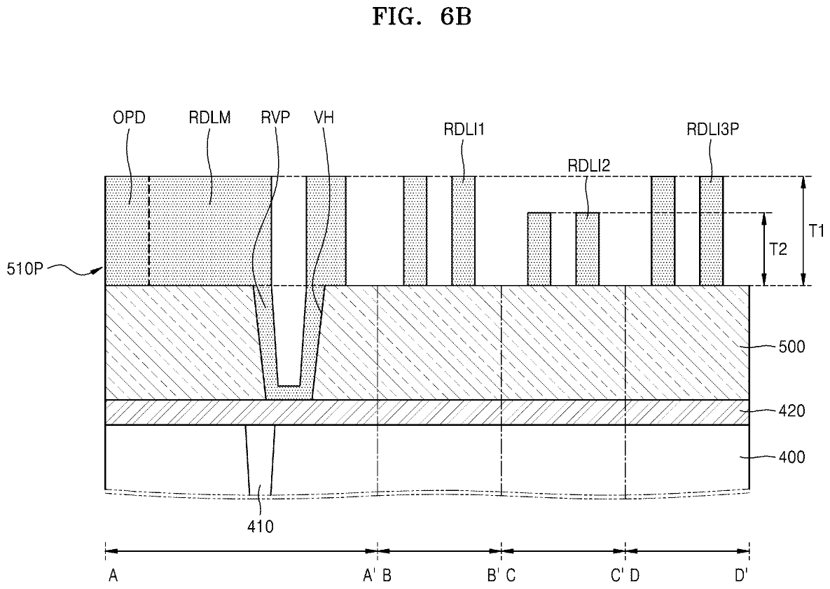

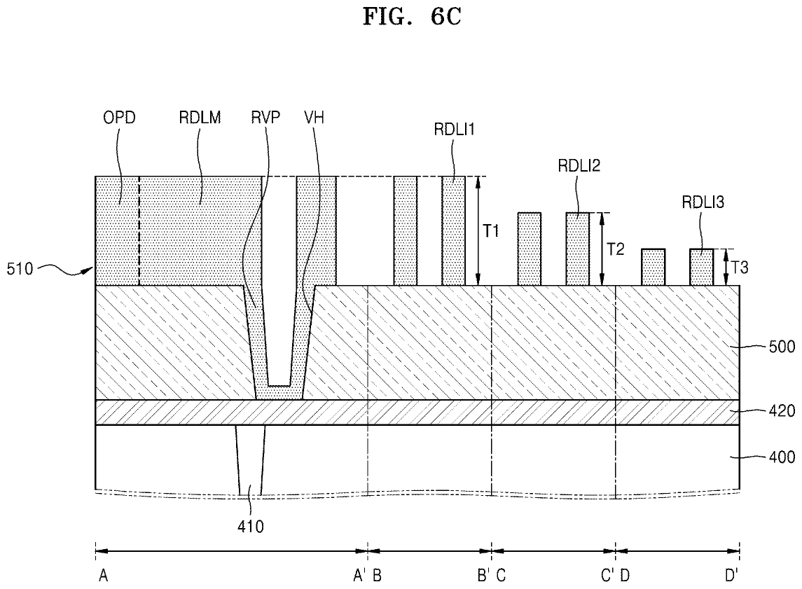

FIGS. 6A to 6C are cross-sectional views sequentially illustrating a method of manufacturing a semiconductor device, according to some example embodiments.

Referring to FIG. 6A, after the inter-wiring insulating layer 400, the upper wiring line 420 on the inter-wiring insulating layer 400, and the wiring via 410 in contact with a lower surface of the upper wiring line 420 and extending through the inter-wiring insulating layer 400 are formed, the redistribution insulating layer 500 may be formed on the inter-wiring insulating layer 400 and the upper wiring line 420. The redistribution via hole VH may pass or extend through the redistribution insulating layer 500 and expose a part of the upper wiring line 420 at a lower surface of the redistribution via hole VH.

A preliminary redistribution conductive layer 510P may be formed to cover a part of an upper surface of the redistribution insulating layer 500 and fill at least a part of the redistribution via hole VH. The preliminary redistribution conductive layer 510P may be formed by forming a preliminary conductive material layer that covers the upper surface of the redistribution insulating layer 500 and fills at least a part of the redistribution via hole VH, and then patterning the preliminary conductive material layer.

The preliminary redistribution conductive layer 510P may be formed to have a first thickness T1 on the upper surface of the redistribution insulating layer 500. The preliminary redistribution conductive layer 510P may include the connection pad OPD, the redistribution line RDLM, the third redistribution via RVP, the first inductor redistribution line RDLI1, a first preliminary inductor line RDLI2P, and a second preliminary inductor line RDLI3P.

Referring to FIGS. 6A and 6B, the second inductor redistribution line RDLI2 may be formed by removing a part of an upper side of the first preliminary inductor line RDLI2P. A part of the upper side of the first preliminary inductor line RDLI2P having the first thickness T1 may be removed to form the second inductor line RDLI2 having the second thickness T2. The second inductor redistribution line RDLI2 may be formed by forming a mask pattern that covers the connection pad OPD, the redistribution line RDLM, the third redistribution via RVP, the first inductor redistribution line RDLI1, and the second preliminary inductor line RDLI3P and that exposes the first preliminary inductor line RDLI2P, and then a part of the upper side of the first preliminary inductor line RDLI2P by using the mask pattern as an etch mask through an etching process.

Referring to FIGS. 6B and 6C, the third inductor redistribution line RDLI3 may be formed by removing a part of an upper side of the second preliminary inductor line RDLI3P. The third inductor redistribution line RDLI3 having the third thickness T3 may be formed by removing a part of the upper side of the second preliminary inductor line RDLI3P having the first thickness T1. The third inductor redistribution line RDLI3 may be formed by forming a mask pattern that covers the connection pad OPD, the redistribution line RDLM, the third redistribution via RVP, the first inductor redistribution line RDLI1, and the second inductor redistribution line RDLI2 and that exposes the second preliminary inductor line RDLI3P, and then removing a part of an upper side of the second preliminary inductor line RDLI3P by using the mask pattern as an etch mask through an etching process.

Thereafter, the protective layer 600 illustrated in FIG. 5 may be formed to form the semiconductor device 1a.

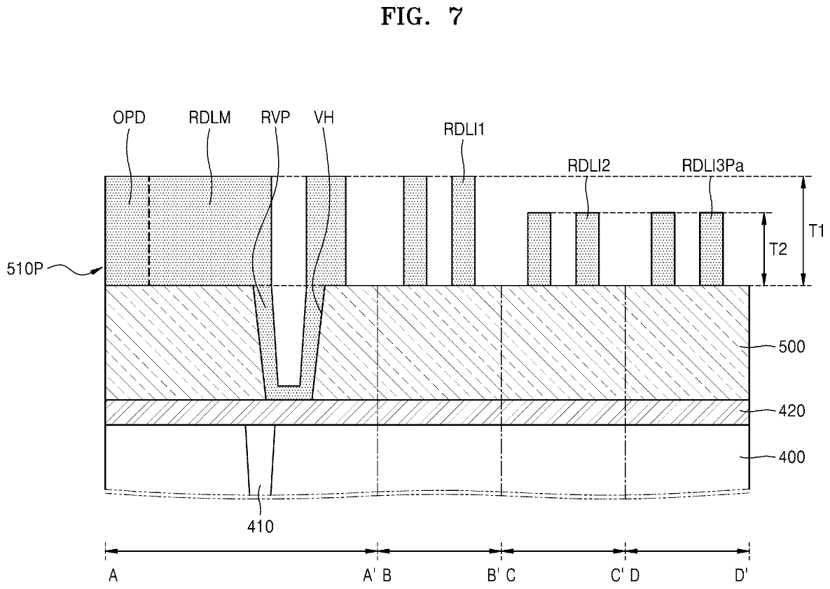

FIG. 7 is a cross-sectional view illustrating a method of manufacturing a semiconductor device, according to some example embodiments.

Referring to FIGS. 6A and 7, the second inductor redistribution line RDLI2 may be formed by removing a part of an upper side of the first preliminary inductor line RDLI2P, and a third preliminary inductor line RDLI3Pa may be formed by removing a part of an upper side of the second preliminary inductor line RDLI3P. The second inductor redistribution line RDLI2 having the second thickness T2 and the third preliminary inductor line RDLI3Pa having the second thickness T2 may be formed by removing a part of an upper side of the first preliminary inductor line RDLI2P having the first thickness T1 and a part of an upper side of the second preliminary inductor line RDLI3P having the first thickness T1. The second inductor redistribution line RDLI2 and the third preliminary inductor line RDLI3Pa may be formed by forming a mask pattern that covers the connection pad OPD, the redistribution line RDLM, the third redistribution via RVP, and the first inductor redistribution line RDLI1 and that exposes the first preliminary inductor line RDLI2P and the second preliminary inductor line RDLI3P, and then removing a part of an upper side of the first preliminary inductor line RDLI2P and a part of an upper side of the second preliminary inductor line RDLI3P by using the mask pattern as an etch mask through an etching process.

Thereafter, referring to FIGS. 7 and 6C, the third inductor redistribution line RDLI3 may be formed by removing a part of an upper side of the third preliminary inductor line RDLI3Pa. The third inductor redistribution line RDLI3 having the third thickness T3 may be formed by removing a part of an upper side of the third preliminary inductor line RDLI3Pa having the second thickness T2.

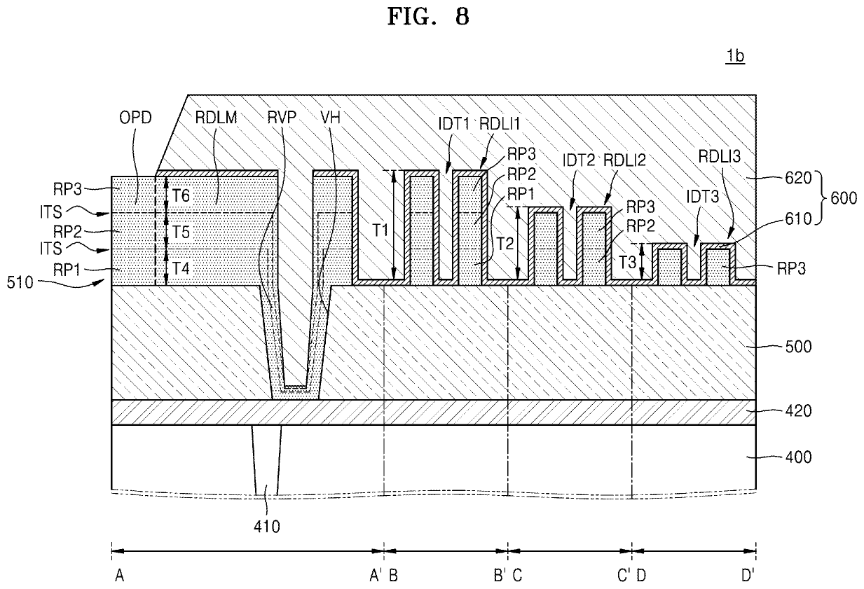

FIG. 8 is a cross-sectional view illustrating a semiconductor device according to some example embodiments. FIG. 8 illustrates a part of the wiring layer BEOL illustrated in FIG. 1 and a portion corresponding to the redistribution layer RDL. Descriptions of FIG. 8 overlapped with the descriptions of FIG. 5 are omitted.

Referring to FIG. 8, a semiconductor device 1b may include an inter-wiring insulating layer 400, an upper wiring line 420 on the inter-wiring insulating layer 400, and a wiring via 410 that is in contact with a lower surface of the upper wiring line 420 and passing through the inter-wiring insulating layer 400.

A redistribution insulating layer 500 may be on the inter-wiring insulating layer 400 and the upper wiring line 420. The redistribution insulating layer 500 may have a redistribution via hole VH. A redistribution conductive layer 510 may be on the redistribution insulating layer 500 and in the redistribution via hole VH.

The redistribution conductive layer 510 may include a first sub-conductive pattern RP1, a second sub-conductive pattern RP2, and a third sub-conductive pattern RP3. The first sub-conductive pattern RP1 may have a fourth thickness T4, the second sub-conductive pattern RP2 may have a fifth thickness T5, and the third sub-conductive pattern RP3 may have a sixth thickness T6. A connection pad OPD, a redistribution line RDLM, a third redistribution via RVP, and a first inductor redistribution line RDLI1 may have a stacked structure of the first sub-conductive pattern RP1, the second sub-conductive pattern RP2, and the third sub-conductive pattern RP3. A second inductor redistribution line RDLI2 may have a stacked structure of the second sub-conductive pattern RP2 and the third sub-conductive pattern RP3. A third inductor redistribution line RDLI3 may include the third sub-conductive pattern RP3. For example, a first thickness T1 may be the sum of the fourth thickness T4, the fifth thickness T5, and the sixth thickness T6, and a second thickness T2 may be the sum of the fifth thickness T5 and the sixth thickness T6, and a third thickness T3 may be equal to the sixth thickness T6.

In some embodiments, the second inductor redistribution line RDLI2 may have a stacked structure of the first sub-conductive pattern RP1 and the second sub-conductive pattern RP2 or may have a stacked structure of the first sub-conductive pattern RP1 and the third sub-conductive pattern RP3. In some embodiments, the third inductor redistribution line RDLI3 may include the first sub-conductive pattern RP1 or the second sub-conductive pattern RP2.

An interface ITS that extends in the horizontal direction may be formed between the first sub-conductive pattern RP1 and the second sub-conductive pattern RP2, between the second sub-conductive pattern RP2 and the third sub-conductive pattern RP3, or between the first sub-conductive pattern RP1 and the third sub-conductive pattern RP3.

For example, the first inductor redistribution line RDLI1 has a stacked structure of the first sub-conductive pattern RP1, the second sub-conductive pattern RP2, and the third sub-conductive pattern RP3, and thus, the first inductor redistribution line RDLI1 may have two interfaces ITS. The second inductor redistribution line RDLI2 has a stacked structure of the second sub-conductive pattern RP2 and the third sub-conductive pattern RP3, a stacked structure of the first sub-conductive pattern RP1 and the second sub-conductive pattern RP2, or a stacked structure of the first sub-conductive pattern RP1 and the third sub-conductive pattern RP3, and thus, the second inductor redistribution line RDLI2 may have one interface ITS. The third inductor redistribution line RDLI3 is composed of the third sub-conductive pattern RP3, the first sub-conductive pattern RP1, or the second sub-conductive pattern RP2, and thus, the third inductor redistribution line RDLI3 may not have any interface ITS.

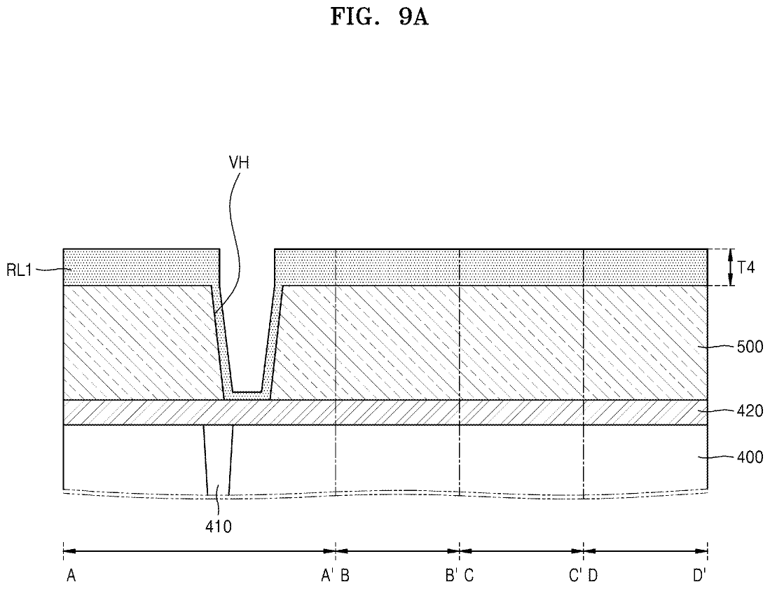

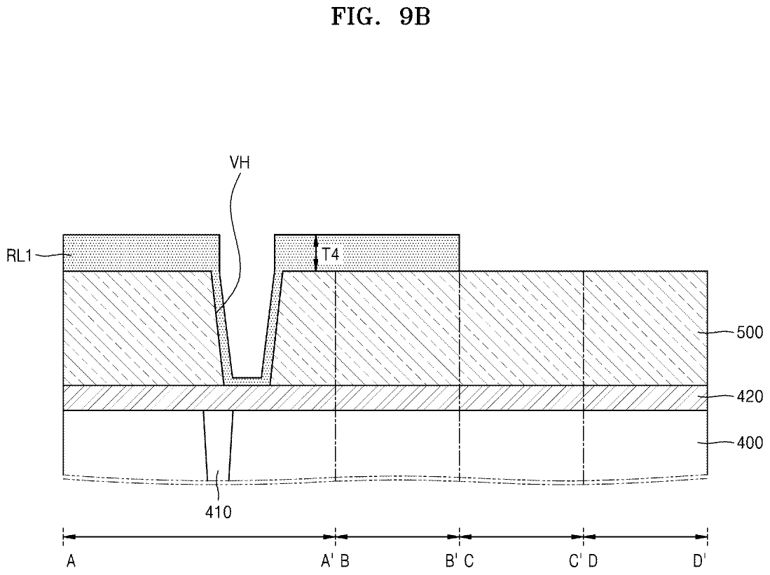

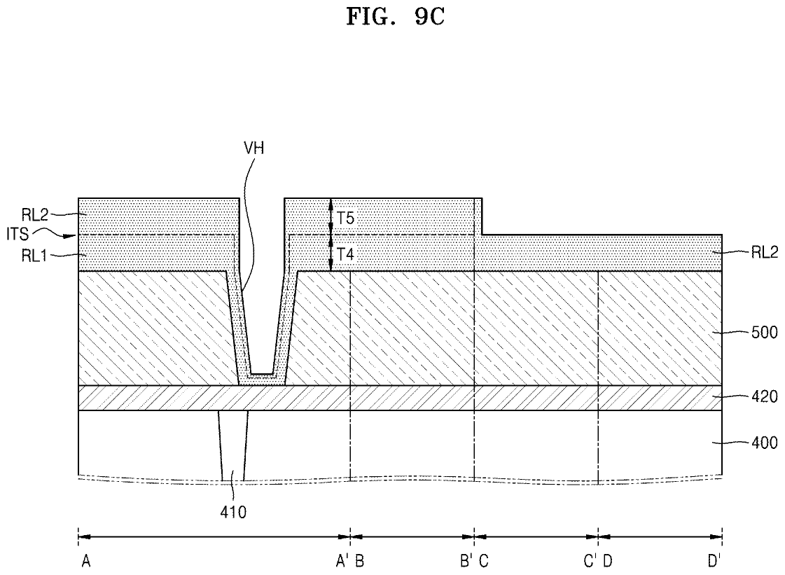

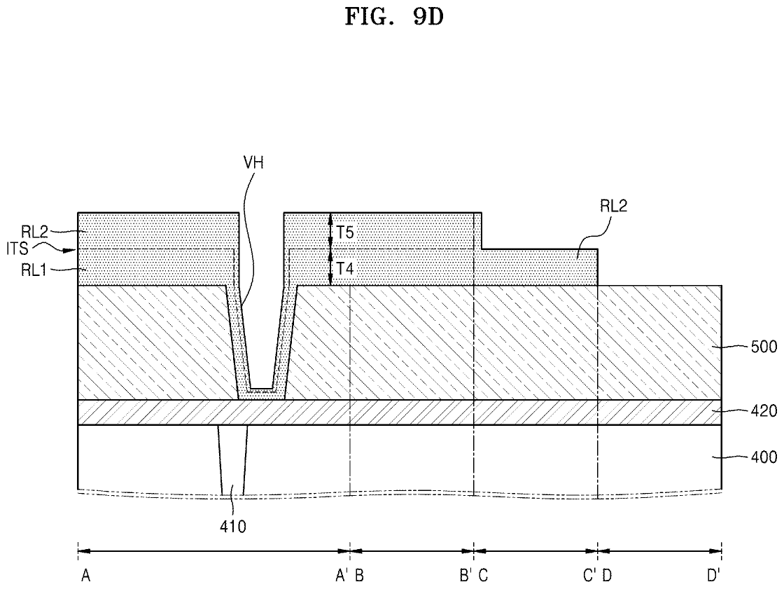

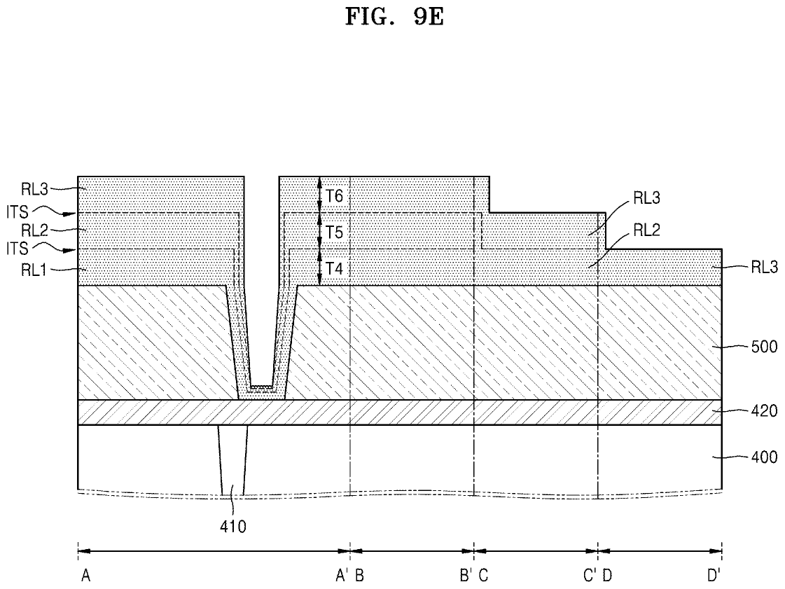

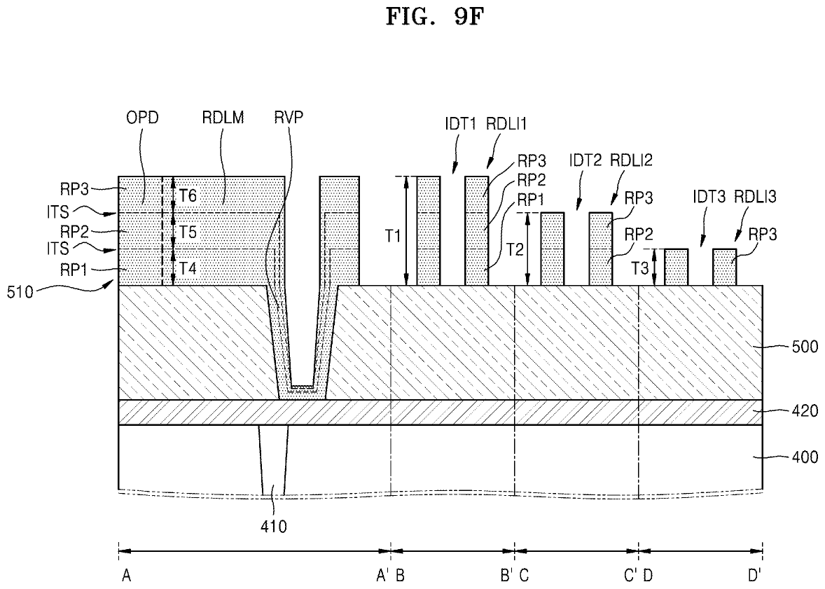

FIGS. 9A to 9F are cross-sectional views sequentially illustrating a method of manufacturing a semiconductor device, according to some example embodiments.

Referring to FIG. 9A, an inter-wiring insulating layer 400, an upper wiring line 420 on the inter-wiring insulating layer 400, and a wiring via 410 in contact with a lower surface of the upper wiring line 420 and extending through the inter-wiring insulating layer 400 are formed, and then a redistribution insulating layer 500 may be formed on the inter-wiring insulating layer 400 and the upper wiring line 420. A redistribution via hole VH may be formed to pass through the redistribution insulating layer 500 and expose a part of the upper wiring line 420 at a lower surface of the redistribution via hole VH. Thereafter, a first sub-conductive layer RL1 may be formed to cover an upper surface of the redistribution insulating layer 500 and to fill at least a part of the redistribution via hole VH. For example, the first sub-conductive layer RL1 may have a fourth thickness T4.

Referring to FIGS. 9A and 9B, a part of the first sub-conductive layer RL1 may be removed. For example, a part of the first sub-conductive layer RL1 formed in portions where the second inductor structure IDT2 and the third inductor structure IDT3 illustrated in FIG. 8 are arranged may be removed, and the other parts of the first sub-conductive layer RL1 formed in portions where the first inductor structure IDT1, the connection pad OPD, the redistribution line RDLM, and the third redistribution via RVP are arranged may not be removed.

Referring to FIG. 9C, a second sub-conductive layer RL2 may be formed on the first sub-conductive layer RL1 and the redistribution insulating layer 500. For example, the second sub-conductive layer RL2 may have a fifth thickness T5. An interface ITS may be formed between the first sub-conductive layer RL1 and the second sub-conductive layer RL2.

Referring to FIG. 9D, a part of the second sub-conductive layer RL2 may be removed. A part of the second sub-conductive layer RL2 formed in a portion where the third inductor structure IDT3 illustrated in FIG. 8 is arranged may be removed, and the other parts of the second sub-conductive layer RL2 formed in portions where the first inductor structure IDT1, the second inductor structure IDT2, the connection pad OPD, the redistribution line RDLM, and the third redistribution via RVP are arranged may not be removed.

Referring to FIG. 9E, a third sub-conductive layer RL3 may be formed on the second sub-conductive layer RL2 and the redistribution insulating layer 500. For example, the third sub-conductive layer RL3 may have a sixth thickness T6. An interface ITS may be formed between the second sub-conductive layer RL2 and the third sub-conductive layer RL3.

Referring to FIG. 9F, a redistribution conductive layer 510 including the first sub-conductive pattern RP1, the second sub-conductive pattern RP2, and the third sub-conductive pattern RP3 may be formed by patterning the first sub-conductive layer RL1, the second sub-conductive layer RL2, and the third sub-conductive layer RL3.

The first sub-conductive pattern RP1 may include a part of each of the connection pad OPD, the redistribution line RDLM, the third redistribution via RVP, and the first inductor redistribution line RDLI1 illustrated in FIG. 8. The second sub-conductive pattern RP2 may include a part of each of the connection pad OPD, the redistribution line RDLM, the third redistribution via RVP, the first inductor redistribution line RDLI1, and the second inductor redistribution line RDLI2 illustrated in FIG. 8. The third sub-conductive pattern RP3 may include a part of each of the connection pad OPD, the redistribution line RDLM, the third redistribution via RVP, the first inductor redistribution line RDLI1, and the second inductor redistribution line RDLI2 illustrated in FIG. 8 and the third inductor redistribution line RDLI3.

Thereafter, the protective layer 600 illustrated in FIG. 8 may be formed, and thus, the semiconductor device 1b may be manufactured.

Referring to FIGS. 4 to 9F, in the semiconductor devices 1a and 1b according to the inventive concepts, inductor structures IDT1, IDT2, and IDT3 having different inductances may be formed by a process of forming the redistribution layer RDL including the connection pad OPD. Accordingly, it is possible to manufacture the semiconductor devices 1a and 1b, each including the inductor structures IDT1, IDT2, and IDT3 that may operate at a high operating speed and various operating voltages while reducing an additional manufacturing process and manufacturing costs.

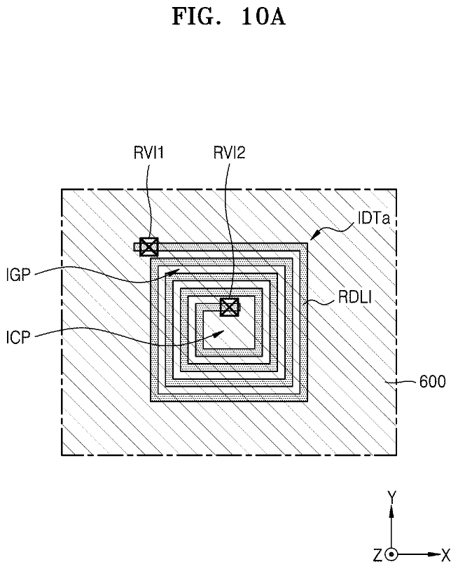

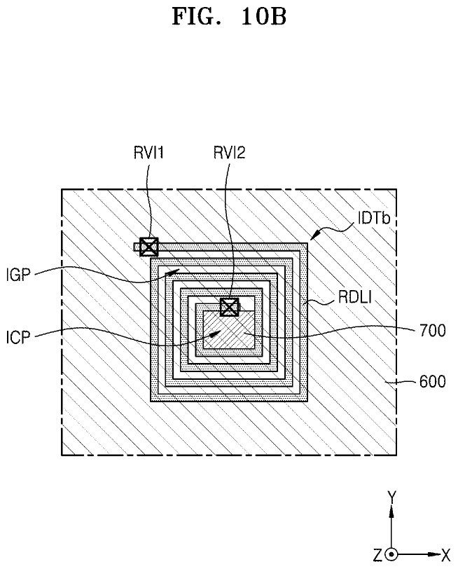

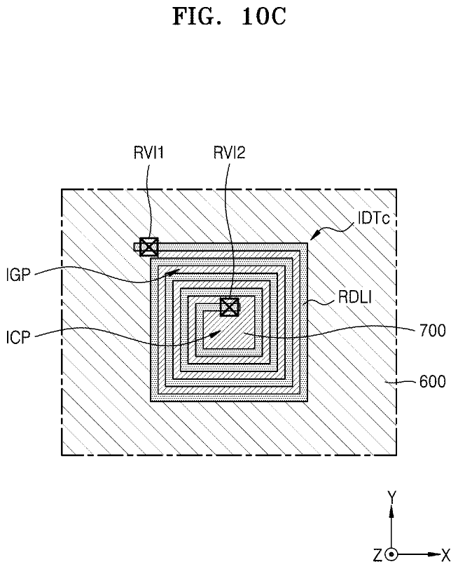

FIGS. 10A to 10C are schematic plan views illustrating inductor structures included in a semiconductor device, according to some example embodiments.

Referring to FIG. 10A, an inductor structure IDTa may be any one of the first inductor structure IDT1, the second inductor structure IDT2, and the third inductor structure IDT3 described with reference to FIGS. 4 to 9F. The inductor structure IDTa may include an inductor redistribution line RDLI extending in a planar coil shape. The inductor redistribution line RDLI may be any one of the first inductor redistribution line RDLI1, the second inductor redistribution line RDLI2, and the third inductor redistribution line RDLI3 described with reference to FIGS. 4 to 9F. A first redistribution via RVI1 and a second redistribution via RVI2 may be respectively connected to both ends of the inductor structure IDTa.

A protective layer 600 may be in a core space ICP and a gap IGP of the inductor structure IDTa. The core space ICP may indicate a space of a central portion of a planar coil shape, and the gap IGP indicates a space between adjacent portions of the inductor redistribution lines RDLI having a coil shape.

Referring to FIG. 10B, an inductor structure IDTb may be any one of the first inductor structure IDT1, the second inductor structure IDT2, and the third inductor structure IDT3 described with reference to FIGS. 4 to 9F. The inductor structure IDTb may include an inductor redistribution line RDLI having a planar coil shape. A first redistribution via RVI1 and a second redistribution via RVI2 may be respectively connected to both ends of the inductor structure IDTb.

A ferromagnetic structure 700 may be in a core space ICP of the inductor structure IDTb, and a protective layer 600 may be filled in a gap IGP. The ferromagnetic structure 700 may include a ferromagnetic material with high magnetic permeability. When the ferromagnetic material has conductivity, the ferromagnetic structure 700 may further include an insulating material layer between the ferromagnetic material and the inductor redistribution line RDLI to separate the ferromagnetic material from the inductor redistribution line RDLI. For example, the ferromagnetic material may include at least one of iron, cobalt, nickel, tantalum, zirconium, barium, zinc, and an alloy material thereof. For example, the insulating material layer may include at least one of silicon oxide, silicon nitride, aluminum nitride, and aluminum oxide.

Referring to FIG. 10C, an inductor structure IDTc may be any one of the first inductor structure IDT1, the second inductor structure IDT2, and the third inductor structure IDT3 described with reference to FIGS. 4 to 9F. The inductor structure IDTc may include an inductor redistribution line RDLI having a planar coil shape. A first redistribution via RVI1 and a second redistribution via RVI2 may be respectively connected to both ends of the inductor structure IDTc.

A ferromagnetic structure 700 may be filled in a core space ICP and a gap IGP of the inductor structure IDTc. The ferromagnetic structure 700 may include a ferromagnetic material. When the ferromagnetic material has conductivity, the ferromagnetic structure 700 may further include an insulating material layer between the ferromagnetic material and the inductor redistribution line RDLI.

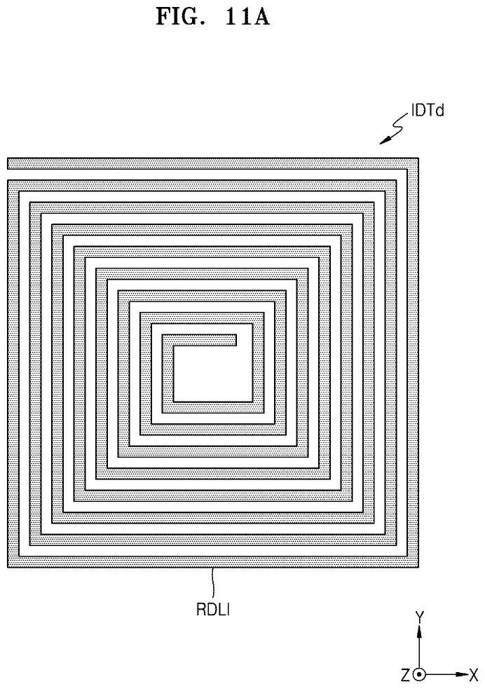

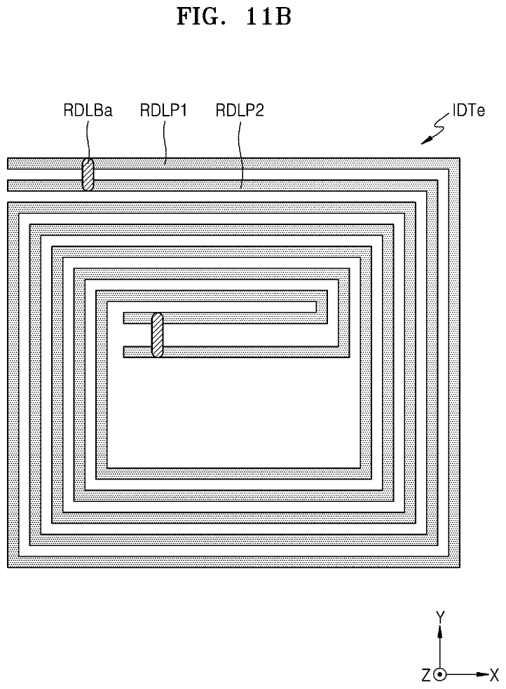

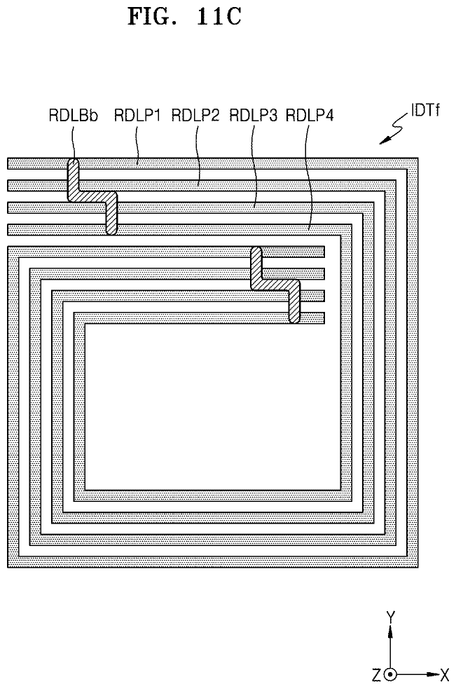

FIGS. 11A to 11C are schematic plan views illustrating inductor structures included in a semiconductor device, according to some example embodiments.

Referring to FIG. 11A, an inductor structure IDTd may be any one of the first inductor structure IDT1, the second inductor structure IDT2, the third inductor structure IDT3, and the inductor structures IDTa, IDTb, and IDTc described with reference to FIGS. 4 to 10C. The inductor structure IDTd may include an inductor redistribution line RDLI having a planar coil shape.

Referring to FIG. 11B, an inductor structure IDTe may be any one of the first inductor structure IDT1, the second inductor structure IDT2, the third inductor structure IDT3, and the inductor structures IDTa, IDTb, and IDTc described with reference to FIGS. 4 to 10C. The inductor structure IDTe may include a first inductor line pattern RDLP1 and a second inductor line pattern RDLP2, each having a planar coil shape.

A pair of inductor bridges RDLBa that connect the first inductor line pattern RDLP1 to the second inductor line pattern RDLP2 may be provided at both ends of the first inductor line pattern RDLP1 and the second inductor line pattern RDLP2. The first inductor line pattern RDLP1 and the second inductor line pattern RDLP2 connected in parallel to each other by the pair of inductor bridges RDLBa may be referred to as an inductor redistribution line.

An inductor structure IDTe includes two inductor line patterns connected in parallel to each other, that is, the first inductor line pattern RDLP1 and the second inductor line pattern RDLP2 connected in parallel to each other by the pair of inductor bridges RDLBa, and thus, the inductor structure IDTe may have reduced resistance.

In some embodiments, the pair of inductor bridges RDLBa may be formed as the redistribution conductive layer 510 described with reference to FIG. 1 and FIGS. 4 to 10C. For example, the first inductor line pattern RDLP1, the second inductor line pattern RDLP2, and the pair of inductor bridges RDLBa may be formed as the redistribution conductive layer 510 to form an integral body.

In some other embodiments, the pair of inductor bridges RDLBa may be formed as the upper wiring line 420 described with reference to FIG. 1 and FIGS. 4 to 10C. For example, the first inductor line pattern RDLP1 and the second inductor line pattern RDLP2 may be formed as the redistribution conductive layer 510 and may be separated from each other and may be electrically connected to each other by the pair of inductor bridges RDLBa that are part of the upper wiring line 420.

Referring to FIG. 11C, an inductor structure IDTf may be any one of the first inductor structure IDT1, the second inductor structure IDT2, the third inductor structure IDT3, and the inductor structures IDTa, IDTb, and IDTc described with reference to FIGS. 4 to 10C. The inductor structure IDTf may include a first inductor line pattern RDLP1, a second inductor line pattern RDLP2, a third inductor line pattern RDLP3, and a fourth inductor line pattern RDLP4, each having a planar coil shape.

A pair of inductor bridges RDLBb connecting the first inductor line pattern RDLP1, the second inductor line pattern RDLP2, the third inductor line pattern RDLP3, and the fourth inductor line pattern RDLP4 to each other may be at both ends of the first inductor line pattern RDLP1, the second inductor line pattern RDLP2, the third inductor line pattern RDLP3, and the fourth inductor line pattern RDLP4. The inductor structure IDTf may include four inductor line patterns connected in parallel to each other, that is, the first inductor line pattern RDLP1, the second inductor line pattern RDLP2, the third inductor line pattern RDLP3, and the fourth inductor line pattern RDLP4 connected in parallel to each other by the pair of inductor bridges RDLBb, and thus, the inductor structure IDTf may have reduced resistance.

In some embodiments, the pair of inductor bridges RDLBb may be formed as the redistribution conductive layer 510 described with reference to FIG. 1 and FIGS. 4 to 10C. In some other embodiments, the pair of inductor bridges RDLBb may be formed as the upper wiring line 420 described with reference to FIG. 1 and FIGS. 4 to 10C.

Although FIGS. 11B and 11C illustrate that each of the inductor structures IDTe and IDTf includes two or four inductor line patterns connected in parallel to each other, the present disclosure is not limited thereto. For example, each of the inductor structures may include three inductor line patterns or five or more inductor line patterns connected in parallel to each other.

While the inventive concepts have been particularly shown and described with reference to some examples of embodiments thereof, it will be understood that various changes in form and details may be made therein without departing from the scope of the following claims.

What is claimed is:

1. A semiconductor device comprising:
a substrate;
an element layer including circuit elements arranged on the substrate;
a wiring layer on the element layer; and
a redistribution layer on the wiring layer,
wherein the redistribution layer includes a redistribution insulating layer and a redistribution conductive layer on the redistribution insulating layer,
wherein the redistribution conductive layer includes a connection pad and first and second inductor structures respectively including first and second inductor redistribution lines having a planar coil shape,
wherein the first and second inductor redistribution lines included in the first and second inductor structures have different thicknesses.

2. The semiconductor device of claim 1, wherein a thickness of the first inductor redistribution line included in the first inductor structure is substantially equal to a thickness of the connection pad.

3. The semiconductor device of claim 2, wherein the first and second inductor structures are of a plurality of inductor structures, and wherein the first inductor redistribution line included in the first inductor structure has a greatest thickness among the inductor redistribution lines included in the plurality of inductor structures.

4. The semiconductor device of claim 2, wherein the thickness of the first inductor redistribution line included in the first inductor structure is greater than a thickness of the second inductor redistribution line included in the second inductor structure.

5. The semiconductor device of claim 4, wherein the first and second inductor structures are of a plurality of inductor structures, and wherein at least one of the plurality of inductor structures comprises a radio frequency (RF) inductor, and at least one of the other inductor structures comprises a power inductor.

6. The semiconductor device of claim 1, wherein a lower surface of the first and second inductor redistribution lines respectively included in each of the first and second inductor structures is at the same vertical level as a lower surface of the connection pad.

7. The semiconductor device of claim 6, wherein the first and second inductor redistribution lines respectively included in each of the first and second inductor structures comprises the same material as the connection pad.

8. The semiconductor device of claim 1, further comprising a protective layer on the redistribution insulating layer and arranged to cover part of the redistribution conductive layer, wherein the connection pad is not covered by the protective layer.

9. The semiconductor device of claim 8, wherein each of a plurality of inductor line patterns is covered by the protective layer.

10. The semiconductor device of claim 8, wherein a ferromagnetic structure including a ferromagnetic material is in a central portion of the inductor redistribution line of each of the first and second inductor structures, and
wherein the protective layer is in a gap that is a space between adjacent portions of the inductor redistribution line of each of the first and second inductor structures.

11. A semiconductor device comprising:
a substrate;
an element layer including circuit elements arranged on the substrate;
a wiring layer formed on the element layer and including an inter-wiring insulating layer, a lower wiring line and an upper wiring line respectively on a lower surface and an upper surface of the inter-wiring insulating layer, and a wiring via passing through the inter-wiring insulating layer and electrically connecting the lower wiring line to the upper wiring line;
a wiring contact plug electrically connecting the lower wiring line to the circuit element; and
a redistribution layer formed on the wiring layer and including a redistribution insulating layer and a redistribution conductive layer,
wherein the redistribution conductive layer includes a plurality of inductor redistribution lines each having a planar coil shape on the redistribution insulating layer, a connection pad connected on the redistribution insulating layer, a connection pad connected redistribution line extending on the redistribution insulating layer, and a redistribution via that extends through the redistribution insulating layer and is electrically connected to the upper wiring line and to one the connection pad connected redistribution line or one of the inductor redistribution line, and
the plurality of inductor redistribution lines include a first inductor redistribution line having a first thickness and a second inductor redistribution line having a second thickness that is less than the first thickness.

12. The semiconductor device of claim 11, wherein the connection pad and the connection pad connected redistribution line have the first thickness.

13. The semiconductor device of claim 11, wherein the connection pad, the connection pad connected redistribution line, and the plurality of inductor redistribution lines comprise the same material, and lower surfaces of the connection pad, the connection pad connected redistribution line, and the plurality of inductor redistribution lines are in contact with an upper surface of the redistribution insulating layer.

14. The semiconductor device of claim 11, further comprising a protective layer arranged to cover the plurality of inductor redistribution lines, the connection pad connected redistribution line, and the redistribution via, on the redistribution insulating layer, and wherein the connection pad is not covered by the protective layer.

15. The semiconductor device of claim 11, wherein the inductor redistribution line includes at least two inductor line patterns that extend in parallel to each other.

16. The semiconductor device of claim 11, wherein each of the connection pad, the connection pad connected redistribution line, and a first inductor redistribution line of the plurality of inductor redistribution lines has a stacked structure of at least two sub-conductive patterns with an interface therebetween.

17. The semiconductor device of claim 11, wherein the circuit element includes dynamic random access memory (DRAM).

18. A semiconductor device comprising:
a substrate having an active region;
a word line provided in the substrate;
an element layer provided on the substrate and including a bit line connected to the active region through a direct contact, and a capacitor structure electrically connected to the active region through a buried contact and a landing pad;
a wiring layer provided on the element layer, and including an inter-wiring insulating layer, a lower wiring line and an upper wiring line respectively on a lower surface and an upper surface of the inter-wiring insulating layer, and a wiring via passing through the inter-wiring insulating layer to electrically connect the lower wiring line to the upper wiring line;
a redistribution layer including a redistribution insulating layer and a redistribution conductive layer on the wiring layer; and
a protective layer covering part of the redistribution conductive layer on the redistribution insulating layer,
wherein the redistribution conductive layer has a planar coil shape on the redistribution insulating layer and includes a plurality of inductor redistribution lines each constituting an inductor structure, a connection pad connected to a connection pad connected redistribution line on the redistribution insulating layer, and a redistribution via passing through the redistribution insulating layer and electrically connected to the upper wiring line and connected to the connection pad connected redistribution line or one of the inductor redistribution lines,
the plurality of inductor redistribution lines include a first inductor redistribution line having a first thickness, a second inductor redistribution line having a second thickness that is less than the first thickness, and a third inductor redistribution line having a third thickness that is less than the second thickness, and
the connection pad connected redistribution line and the connection pad have the first thickness.

19. The semiconductor device of claim 18, wherein
the inductor structures include a first inductor structure having the first inductor redistribution line, a second inductor structure having the second inductor redistribution line, and a third inductor structure having the third inductor redistribution line,
the first inductor redistribution line, the second inductor redistribution line, and the third inductor redistribution line have the same width, and
the third inductor structure has greater inductance than the second inductor structure, and the second inductor structure has greater inductance than the first inductor structure.

20. The semiconductor device of claim 19, wherein the first inductor structure, the second inductor structure, and the third inductor structure comprise power inductors operating in response to different operating voltages from each other.
